(19) United States
(12) Patent Application Publication
(10) Pub. No.: US 2009/0051278 A1
(43) Pub. Date: Feb. 26, 2009

(54) ORGANIC ELECTROLUMINESCENT DISPLAY DEVICE HAVING SCATTERING MEMBER

(75) Inventors: Ryuji SANETO, Minami-Ashigara-shi (JP); Yujiro YANAI, Minami-Ashigara-shi (JP); Yukito SAITOH, Minami-Ashigara-shi (JP)

Correspondence Address: BUCHANAN, INGERSOLL & ROONEY PC, POST OFFICE BOX 1404, ALEXANDRIA, VA, 22313-1404, US

(73) Assignee: FUJIFILM CORPORATION, Tokyo (JP)

(21) Appl. No.: 12/195,785

(22) Filed: Aug. 21, 2008

(30) Foreign Application Priority Data
Aug. 21, 2007 (JP) 2007-215278
Aug. 20, 2008 (JP) 2008-211813

(51) Int. Cl. H01L 51/54

(52) U.S. Cl. 313/504

(57) ABSTRACT

An organic electroluminescent display device includes: a substrate; a lower electrode; an organic electroluminescent layer; and an upper electrode, in this order, wherein the organic electroluminescent display device further comprises a scattering member on or above the upper electrode.

### BACKGROUND OF THE INVENTION

1. Field of the Invention

The present invention relates to an organic electroluminescent display device enhanced in the light emission efficiency by using a scattering member.

2. Description of the Related Art

The organic electroluminescent display device (organic EL display device) is a self-emission type display device and used for the purpose of display or lighting. The organic EL display has an advantage in view of display performance, such as high visibility in comparison with conventional CRT or LCD or no viewing angle dependency, and is also advantageous in that the display can be lightweighted or thinned. On the other hand, the organic EL lighting has a possibility that lighting in a heretofore unrealizable shape can be realized by using a flexible substrate, in addition to the advantage such as lightweighting or thinning.

The organic EL display device or inorganic EL display device has the above-described excellent properties, but the refractive index of each of layers constituting the display device, including a light-emitting layer, is generally higher than that of air. For example, in an organic EL display devices the refractive index of an organic thin-film layer such as light-emitting layer is from 1.6 to 2.1. Therefore, the light emitted readily causes total reflection at the interface and the light extraction efficiency is less than 20%. Thus, the majority of light is lost.

This light loss in an organic EL display device is reviewed by referring to FIG. 1.

The organic EL display device is fundamentally fabricated such that, as shown in FIG. 1, a back electrode 2, an organic layer 3 composed of two or three layers including a light-emitting layer, a transparent electrode 4 and a transparent substrate 5 are stacked on a TFT substrate 1, and a hole injected from the back electrode 2 and an electron injected from the transparent electrode 4 are recombined in the organic layer 3 to excite a fluorescent substance or the like, whereby light is emitted. The light emitted from the organic layer 3 is output from the transparent substrate 5 directly or after being reflected from the back electrode 2 formed of aluminum or the like.

However, as shown in FIG. 1, light generated inside of the display device causes total reflection depending on the angle of light incident on the interface with an adjacent layer differing in the refractive index, and the light is entirely waveguided through the inside of the display derive and cannot be extracted to the outside (light of Lb and Lc in FIG. 1). The percentage of this waveguided light is determined by the refractive index relative to the adjacent layer and in the case of a general organic EL display device (air (n=1.0)/transparent substrate (n=1.5)/transparent electrode (n=2.0)/organic layer (n=1.7)/back electrode), the percentage of light which is not released to the atmosphere (air) but is waveguided through the inside of the display devices becomes about 81%. That is, only about 19% of the entire light emission quantity cannot be effectively utilized.

Accordingly, the measures required for enhancing the light extraction efficiency are: (a) to extract light totally reflected from the transparent substrate/air interface and waveguided through the “organic layer+transparent electrode+transparent substrate” (Lb in FIG. 1); and (b) to extract light totally reflected from the transparent electrode/transparent substrate interface and waveguided through the “organic layer+transparent electrode” (Lc in FIG. 1).

Out of these measures, with respect to (a), a method of preventing total reflection from the transparent substrate/air interface by forming irregularities on the transparent substrate surface has been proposed (see, for example, U.S. Pat. No. 4,774,435).

With respect to (b), a method of processing the transparent electrode/transparent substrate interface or light-emitting layer/adjacent layer interface to have a diffraction grating has been proposed (see, for example, JP-A 11-283751 (the term “JP-A” as used herein means an “unexamined published Japanese patent application”) and JP-A-2002-313554). Also, a method of increasing the light emission efficiency by processing the interface between stacked organic layers to have irregularities has been proposed (see, for example, JP-A-2002-313567). Among them, in the method of forming a diffraction grating at the light-emitting layer/adjacent layer interface, the adjacent layer comprises an electrically conductive medium, the depth of irregularities of the diffraction grating is about 40% based on the film thickness of the light-emitting layer, and the pitch and depth of irregularities are set to be in a specific relationship, whereby the waveguided light is extracted. In the method of forming irregularities at the interface between organic layers, the adjacent layers across irregularities each comprises an electrically conductive medium, and irregularities having a depth of about 20% based on the film thickness of the light-emitting layer and a tilt angle of 30° with respect to the interface are formed at the interface between organic layers to enlarge the interface at which the organic layers are joined together, whereby the light emission efficiency is increased.

However, these methods have such a problem as that the processing is difficult or dielectric breakdown readily occurs at the time of passing a current. In order to elevate the efficiency of the display device, further development of a useful method for extracting light is demanded.

As one of the means for solving these problems, for example, a technique of providing a light scattering layer on the surface of an organic EL surface emitter to improve the extraction efficiency has been proposed (see, for example, JP-A-2003-109747 and JP-A-2003-173877). However, occurrence of light scattering on the surface brings about a problem that light is greatly blurred and resolution deteriorates.

To solve this problem, a method of disposing a light diffusing layer right above the upper electrode to reduce blurring of an image while improving the light extraction efficiency has been proposed (see, for example, JP-A-2006-107744).

However, in this method, the refractive index of the material used as the base material of the light diffusing layer is from 1.5 to 1.6 and is improper for the efficient extraction of light waveguided through an organic layer+a transparent electrode.

### SUMMARY OF THE INVENTION

Accordingly, an object of the present invention is to provide a light-emitting display device with high light extraction efficiency and less image blurring, which is a self-emission type light-emitting display device where the light emission site has a refractive index higher than the refractive index of air. In particular, an object of the present invention is to provide an organic electroluminescent display device enhanced in the extraction efficiency of light waveguided through “an organic layer+a transparent electrode”.

The object of the present invention can be attained by the organic electroluminescent display device described in (1) to (22) below.

(1) An organic electroluminescent display device, comprising:

a substrate,

a lower electrode;

an organic electroluminescent layer; and

an upper electrode, in this order,

wherein the organic electroluminescent display device further comprises a scattering member on or above the upper electrode.

(2) The organic electroluminescent display device as described in (1) above,

wherein the scattering member is a light diffusing film.

(3) The organic electroluminescent display device as described in (2) above,

wherein the light diffusing film contains:

a transparent substrate film; and

a light diffusing layer that contains:
a transparent resin composition; and
a light scattering particle, the light scattering particle having a refractive index different from a refractive index of the transparent resin composition,
wherein the refractive index of the transparent resin composition contained in the light diffusing layer is 1.6 or more.

(4) The organic electroluminescent display device as described in (3) above,

wherein the transparent resin composition of the light diffusing layer contains at least one kind of an inorganic fine particle selected from the group consisting of ZrO₂, TiO₂, SnO₂ and ZnO.

(5) The organic electroluminescent display device as described in (3) or (4) above,

wherein the refractive index of the light scattering particle contained in the light diffusing layer is 1.55 or less.

(6) The organic electroluminescent display device as described in any of (3) to (5) above,

wherein an average diameter of the light scattering particle contained in the light diffusing layer is from 0.1 to 2.0 μm.

(7) The organic electroluminescent display device as described in (2) above,

wherein the light diffusing film contains:

a transparent substrate film; and

a light diffusing layer that contains:
a transparent resin composition; and
at least one kind of fine particle selected from the group consisting of ZrO₂, TiO₂, SnO₂ and ZnO contained in the transparent resin composition, the at least one kind of fine particle having an average particle diameter of 50 to 300 nm.

(8) The organic electroluminescent display device as described in any of (3) to (7) above,

wherein the light diffusing film further contains a low refractive index layer between the transparent substrate film and the light diffusing layer.

(9) The organic electroluminescent display device as described in (8) above,

wherein a refractive index of the low refractive index layer is 1.45 or less.

(10) The organic electroluminescent display device as described in (8) or (9) above,

wherein the low refractive index layer contains a hollow silica.

(11) The organic electroluminescent display device as described in (1) above,

wherein the scattering member is a color filter.

(12) The organic electroluminescent display device as described in (11) above,

wherein the color filter is obtained by curing a curable composition containing a colorant and a light scattering particle.

(13) The organic electroluminescent display device as described in (12) above,

wherein a refractive index of the curable composition at the curing is 1.6 or more.

(14) The organic electroluminescent display device as described in (12) or (13) above,

wherein the curable composition contains at least one kind of an inorganic fine particle selected from the group consisting of ZrO₂, TiO₂, SnO₂ and ZnO.

(15) The organic electroluminescent display device as described in any of (12) to (14) above,

wherein a refractive index of the light scattering particle is 1.55 or less.

(16) The organic electroluminescent display device as described in any of (12) to (15) above,

wherein an average diameter of the light scattering particle is from 0.1 to 2.0 μm.

(17) The organic electroluminescent display device as described in (12) above,

wherein the light scattering particle is at least one kind of fine particle selected from the group consisting of ZrO₂, TiO₂, SnO₂ and ZnO having an average particle diameter of 50 to 300 nm.

(18) The organic electroluminescent display device as described in any of (1) to (17) above,

wherein the scattering member is laminated directly on the upper electrode.

(19) The organic electroluminescent display device as described in any of (1) to (17) above,

wherein the scattering member is laminated on the upper electrode through a barrier layer and laminated directly on the barrier layer.

(20) The organic electroluminescent display device as described in any of (2) to (17) above,

wherein the light diffusing film is laminated on the upper electrode or a barrier layer provided on the upper electrode through an adhesion layer.

(21) The organic electroluminescent display device as described in (20) above,

wherein a refractive index of the adhesion layer is 1.6 or more.

(22) The organic electroluminescent display device as described in (20) or (21) above,

wherein the adhesion layer contains at least one kind of an inorganic fine particle selected from the group consisting of ZrO₂, TiO₂, SnO₂ and ZnO.

### BRIEF DESCRIPTION OF THE DRAWINGS

FIG. 1 represents a view for explaining the cause of decrease in the light extraction efficiency in a self-emission display device;

FIG. 2 represents a cross-sectional view of the light diffusing film comprising a transparent substrate film and a light diffusing layer according to the present invention;

FIG. 3 represents a cross-sectional view of the light diffusing film comprising a transparent substrate film, a low refractive index layer and a light diffusing layer according to the present invention;

FIG. 4 represents a schematic view showing the basic construction of the organic EL display device according to the present invention;

FIG. 5 represents a view showing the constructions of Examples 1, 4 to 6 and 10 according to the present invention; and

FIG. 6 represents a view showing the constructions of Examples 2, 7 to 9 and 11 according to the present invention, wherein 1 denotes TFT substrate; 2 denotes back electrode; 3 denotes organic layer; 4 denotes transparent electrode; 5 denotes transparent substrate; 10 denotes light diffusing film 1; 11 denotes light diffusing film 2; 20 denotes transparent substrate film; 30 denotes light diffusing layer; 31 denotes light-transmitting resin; 41 denotes light scattering particle; 50 denotes low refractive index layer; 100 denotes basic construction of organic EL display device; 101 denotes device construction of Example 1; 102 denotes device construction of Example 2; 110 denotes TFT substrate; 120 denotes lower electrode; 130 denotes organic EL layer; 140 denotes upper electrode; 150 denotes barrier layer; 160 denotes transparent substrate; and 170 denotes adhesion layer.

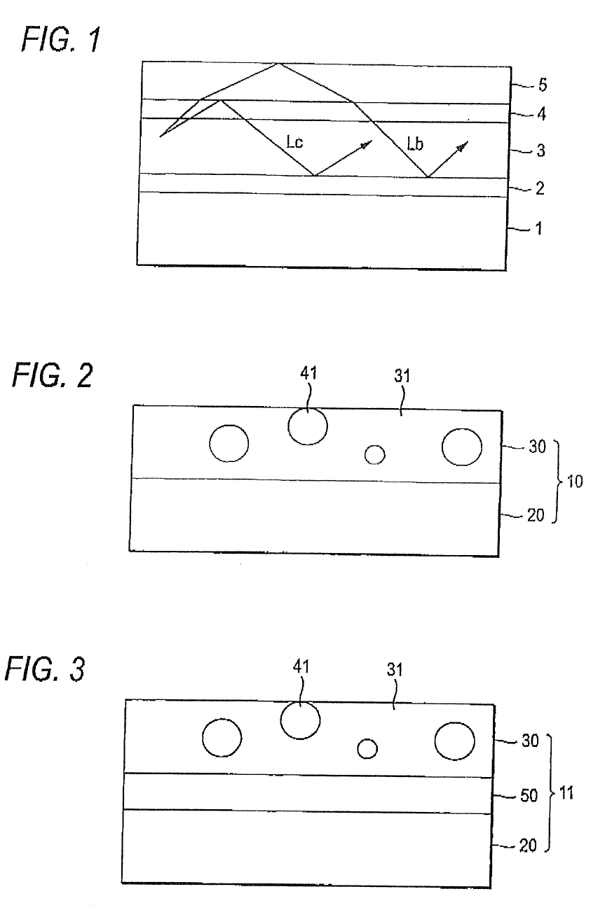

### DETAILED DESCRIPTION OF THE INVENTION

The organic electroluminescent display device of the present invention comprises a lower electrode formed on a substrate, an organic electroluminescent layer formed on the lower electrode, and an upper electrode formed on the organic electroluminescent layer, and has a scattering member on the upper electrode.

The scattering member, organic electroluminescent display device and adhesive according to the present invention are described in detail below.

### <<Scattering Member>>

A light diffusing film or a color filter can be selected as the scattering member. The light diffusing film and color filter for use in the present invention are described in detail below.

### <Light Diffusing Film>

FIG. 2 is a cross-sectional schematic view showing the basic construction of the light diffusing film. The light diffusing film (10) shown in FIG. 2 comprises a stack of a transparent substrate film (20) and a light diffusing layer (30). The light diffusing layer (30) contains a light scattering particle (41) in a light-transmitting resin (31). The light diffusing layer (30) may be composed of a plurality of layers. Also, two or more kinds of light scattering particles may be used. Furthermore, a light diffusing film (11) shown in FIG. 3 having a construction where a low refractive index layer (50) is inserted between the transparent substrate film (20) and the light diffusing layer (30) can also enhance the light extraction efficiency.

### <Light Diffusing Layer>

The light diffusing layer (30) comprises a light scattering particle (41) and a light-transmitting resin (31). The scattered light profile and haze value are adjusted by the refractive index and particle size of each of the light scattering particle (41) and the light-transmitting resin (31).

The refractive index of the light scattering particle (41) of the light diffusing layer (30) is preferably 1.55 or less, more preferably from 1.36 to 1.50, because a refractive index difference from the light transmitting resin layer becomes 0.05 or more and sufficient scattering amount can be obtained. The refractive index of the low refractive index layer (50) is preferably from 1.45 or less, more preferably from 1.30 to 1.45, because a refractive index difference from air becomes 0.45 or less and total reflection can be suppressed. The refractive index of triacetyl cellulose preferably used as the transparent substrate film (20) is 1.48. By elevating the refractive index of the light diffusing layer (30), an excellent effect of enhancing the light extraction efficiency is obtained.

### <Light Scattering Particle>

The difference in the refractive index between the light scattering particle (41) and the light-transmitting resin (31) constituting the entire light diffusing layer (30) is preferably 0.02 or more. If the difference in the refractive index is less than 0.02, the light diffusing effect is not obtained due to too small difference in the refractive index therebetween. In the present invention, in order to enhance the light extraction efficiency, the light totally reflected at the interface needs to be diffused. As the diffusion effect is larger, the light extraction efficiency is more enhanced.

As for the light scattering particle (41), only one kind of a particle may be used, or a plurality of kinds of particles may be used in combination.

The light scattering particle (41) is not limited in its kind and may be an organic fine particle or an inorganic fine particle. Examples of the organic fine particle include a polymethyl methacrylate bead, an acryl-styrene copolymer bead, a melamine bead, a polycarbonate bead, a styrene bead, a crosslinked polystyrene bead, a polyvinyl chloride bead, and a benzoguanamine-melamine formaldehyde bead. Examples of the inorganic fine particle include SiO₂ (e.g. amorphous silica-based bead), ZrO₂, TiO₂, Al₂O₃, In₂O₃, ZnO, SnO₂ and Sb₂O₃.

The average diameter (particle size) of the light scattering particle (41) is preferably from 0.1 to 2.0 μm, because a scattering amount can be sufficiently obtained and the directional characteristics of light scattering become almost isotropic scattering. By making the directional characteristics close to isotropic scattering, more amount of light can be extracted.

In the case of such a light scattering particle (41), the light scattering particle is liable to precipitate in the light-transmitting resin (31) and therefore, an inorganic filler such as silica may be added to prevent the precipitation. Incidentally, as the amount of the inorganic filler added becomes larger, this is effective in preventing the light scattering particle from precipitation but adversely affects the transparency of the coating film. Accordingly, an inorganic filler having a particle diameter of 0.5 μm or less is preferably incorporated into the light-transmitting resin (31) to such an extent as not impairing the transparency of the coating film, that is, in an amount of less than about 0.1 mass %. (In this specification, mass ratio is equal to weight ratio.)

### <Light-Transmitting Resin>

As for the light-transmitting resin (31), resins which are cured by any of ultraviolet rays, electron beams and heat are mainly used. More specifically, three kinds of resins, that is, a photo-curable resin, an ionizing radiation-curable resin and a heat-curable resin, are used. In addition, as for these curable resins, the mixture of a thermoplastic resin and a solvent is used. The thickness of the light diffusing layer (30) is usually on the order of 0.5 to 50 μm, preferably from 1 to 20 μm, more preferably from 2 to 10 μm, and most preferably from 3 to 7 μm.

The binder used for the light-transmitting resin (31) is preferably a polymer having a saturated hydrocarbon or a polyether as the main chain, more preferably a polymer having a saturated hydrocarbon as the main chain. Also, the binder is preferably crosslinked. The polymer having a saturated hydrocarbon as the main chain is preferably obtained by a polymerization reaction of an ethylenically unsaturated monomer. In order to obtain a crosslinked binder, a monomer having two or more ethylenically unsaturated groups is preferably used.

Examples of the monomer having two or more ethylenically unsaturated groups include an ester of polyhydric alcohol and (meth)acrylic acid (e.g., ethylene glycol di(meth)acrylate, 1,4-dichlohexane diacrylate, pentaerythritol tetra(meth)acrylate, pentaerythritol tri(meth)acrylate, trimethylolpropane tri(meth)acrylate, trimethylolethane tri(meth)acrylate, dipentaerythritol tetra(meth)acrylate, dipentaerythritol penta(meth)acrylate, dipentaerythritol hexa(meth)acrylate, 1,3,5-cyclohexanetriol trimethacrylate, polyurethane polyacrylate, polyester polyacrylate), a vinyl benzene derivative (e.g., 1,4-divinylbenzene, 4-vinylbenzoic acid-2-acryloylethyl ester, 1,4-divinylcyclohexanone), a vinylsulfone (e.g., divinylsulfone), an acrylamide (e.g., methylenebisacrylamide), and a methacrylamide. Among these, an acrylate or methacrylate monomer having at least three functional groups is preferred, and an acrylate monomer having at least five functional groups is more preferred in view of film hardness, that is, scratch resistance. A mixture of dipentaerythritol pentaacrylate and dipentaerythritol hexaacrylate is commercially available and is particularly preferred.

The monomer having an ethylenically unsaturated group is dissolved in a solvent together with a polymerization initiator of various types and other additives, and the obtained solution is coated, dried and then subjected to a polymerization reaction using light, ionizing radiation or heat, whereby the coating can be cured.

A crosslinked structure may be introduced into the binder by the reaction of a crosslinking group, in place of or in addition to the polymerization of a monomer having two or more ethylenically unsaturated groups. Examples of the crosslinking functional group include an isocyanate group, an epoxy group, an aziridine group, an oxazoline group, an aldehyde group, a carbonyl group, a hydrazine group, a carboxyl group, a methylol group and an active methylene group. Also, a vinylsulfonic acid, an acid anhydride, a cyanoacrylate derivative, melamine, an etherified methylol, an ester, or a metal alkoxide such as urethane and tetramethoxysilane may be used as a monomer for introducing a crosslinked structure. A functional group which exhibits the crosslinking property as a result of the decomposition reaction, such as blocked isocyanate group, may also be used. That is, the crosslinking functional group for use in the present invention is not limited to a functional group which directly causes a reaction but may be a group which exhibits reactivity after the decomposition. The binder having such a crosslinking functional group is coated and then heated, whereby a crosslinked structure can be formed.

The light-transmitting resin (31) is preferably formed from, in addition to the above-described binder polymer, a monomer having a high refractive index and/or a metal oxide ultrafine particle having a high refractive index. Examples of the monomer having a high refractive index include bis(4-methacryloylthiophenyl)sulfide, vinylnaphthalene, vinylphenyl sulfide and 4-methacryloxyphenyl-4′-methoxyphenyl thioether. As for the metal oxide ultrafine particle having a high refractive index, it is preferred to contain a fine particle having a particle diameter of 100 nm or less, preferably 50 nm or less, and comprising an oxide of at least one metal selected from the group consisting of zirconium, titanium, aluminum, indium, zinc, tin and antimony. The metal oxide ultrafine particle having a high refractive index is preferably an oxide ultrafine particle of at least one metal selected from the group consisting of Al, Zr, Zn, Ti, In and Sn, and specific examples thereof include ZrO₂, TiO₂, Al₂O₃, In₂O₃, ZnO, SnO₂, Sb₂O₃ and ITO. Among these, ZrO₂ is more preferred. The amount added of the monomer or metal oxide ultrafine particle having a high refractive index is preferably from 10 to 90 mass %, more preferably from 20 to 80 mass %, based on the total mass of the light-transmitting resin (31).

In the case where the light-transmitting resin (31) and the transparent substrate film (20) are in contact, for satisfying both the expression of antiglare property and the adhesion between the support and the antiglare layer, the solvent of the coating solution for forming the light-transmitting resin (31) is composed of at least one or more kinds of solvents capable of dissolving the transparent substrate film (20) (for example, a triacetyl cellulose support) and at least one or more kinds of solvents incapable of dissolving the transparent substrate film (20). At least one kind of a solvent out of the solvents incapable of dissolving the transparent substrate film (20) preferably has a boiling point higher than that of at least one kind of a solvent out of the solvents capable of dissolving the transparent substrate film (20). It is more preferred that the difference in the boiling point temperature between the solvent having a highest boiling point out of the solvents incapable of dissolving the transparent substrate film (20) and the solvent having a highest boiling point out of the solvents capable of dissolving the transparent substrate film (20) is 30° C. or more. The difference in the boiling point temperature is most preferably 50° C. or more.

Examples of the solvent capable of dissolving the transparent substrate film (20) include ethers having a carbon number of 3 to 12, specifically, dibutyl ether, dimethoxymethane, dimethoxyethane, diethoxyethane, propylene oxide, 1,4-dioxane, 1,3-dioxolan, 1,3,5-trioxane, tetrahydrofuran, anisole and phenetol; ketones having a carbon number of 3 to 12, specifically, acetone, methyl ethyl ketone, diethyl ketone, dipropyl ketone, diisobutyl ketone, cyclopentanone, cyclohexanone, methyl cyclohexanone and methyl cyclohexanone; esters having a carbon number of 3 to 12, specifically, ethyl formate, propyl format, n-pentyl formate, methyl acetate, ethyl acetate, methyl propionate, ethyl propionate, n-pentyl acetate and γ-butyrolactone; and an organic solvent having two or more functional groups, specifically, methyl 2-methoxyacetate, methyl 2-ethoxyacetate, methyl 2-ethoxyacetate, ethyl 2-ethoxypropionate, 2-methoxyethanol, 2-propoxyethanol, 2-butoxyethanol, 1,2-diacetoxyacetone, acetylacetone, diacetone alcohol, methyl acetoacetate and ethyl acetoacetate. One of these solvents may be used alone, or two or more thereof may be used in combination. The solvent capable of dissolving the transparent substrate is preferably a ketone-based solvent.

Examples of the solvent incapable of dissolving the transparent substrate film (20) include methanol, ethanol, 1-propanol, 2-propanol, 1-butanol, 2-butanol, tert-butanol, 1-pentanol, 2-methyl-2-butanol, cyclohexanol, isobutyl acetate, methyl isobutyl ketone, 2-octanone, 2-pentanone, 2-hexanone, 2-heptanone, 3-pentanone, 3-heptanone and 4-heptanone. One of these solvents may be used alone, or two or more thereof may be used in combination.

The mass ratio (A/B) between the total amount (A) of the solvents capable of dissolving the transparent substrate film and the total amount (B) of the solvents incapable of dissolving the transparent substrate film is preferably from 5/95 to 50/50, more preferably from 10/90 to 40/60, still more preferably 15/85 to 30/70.

As for the method of curing the photo-curable resin composition, a normal curing method for photo-curable resin compositions, that is, curing by irradiation with ultraviolet ray, may be used. As for the method of curing the ionizing radiation curable resin composition, a normal curing method for ionizing radiation-curable resin compositions, that is, curing by irradiation with electron beam may be used.

For example, in the case of electron beam curing, an electron beam having an energy of 50 to 1,000 KeV, preferably from 100 to 300 KeV, emitted from various electron beam accelerators such as Cockroft-Walton type, Van de Graff type, resonance transformer type, insulating core transformer type, linear type, Dynamitron type and high-frequency type may be used, and in the case of ultraviolet ray curing, an ultraviolet ray emitted from light of an ultrahigh pressure mercury lamp, a high pressure mercury lamp, a low pressure mercury lamp, carbon arc, xenon arc, a metal halide lamp or the like may be used.

### <Low Refractive Index Layers>

The low refractive index layer (50) is provided between the transparent substrate film (20) and the light diffusing layer (30) for the purpose of imparting a function of more enhancing the light extraction efficiency (see, FIG. 3). The low refractive index layer (50) can produce the light extraction efficiency enhancing effect when combined with the light diffusing layer (30). The refractive index of the low refractive index layer is, as described above, preferably from 1.30 to 1.45, and the thickness of the low refractive index layer is preferably more than about λ/4 and is preferably 100 nm or more.

For the low refractive index layer (50) of the present invention, a fluorine-containing resin obtained by curing a heat-curable or photo-curable crosslinking fluorine-containing compound is used. By virtue of this resin, excellent scratch resistance is ensured when the layer is used as an outermost layer, in comparison with a low refractive index layer using magnesium fluoride or calcium fluoride. The refractive index of the heat-curable or photo-curable crosslinking fluorine-containing compound is preferably from 1.30 to 1.45. The dynamic friction coefficient of the cured fluorine-containing resin is preferably from 0.03 to 0.15, and the contact angle for water is preferably from 90 to 120°. Examples of such a crosslinking fluorine-containing compound include a perfluoroalkyl group-containing silane compound (e.g., (heptadecafluoro-1,1,2,2-tetradecyl)triethoxysilane), and a fluorine-containing copolymer produced from, as constituent units, a fluorine-containing monomer and a monomer for imparting a crosslinking group.

Specific examples of the fluorine-containing monomer unit include fluoroolefins (e.g., fluoroethylene, vinylidene fluoride, tetrafluoroethylene, hexafluoroethylene, hexafluoropropylene, perfluoro-2,2-dimethyl-1,3-dioxol), partially or completely fluorinated alkyl ester derivatives of (meth)acrylic acid (e.g., Viscoat 6FM (produced by Osaka Organic Chemical Industry, Ltd.), M-2020 (produced by Daikin Industries, Ltd.)), and completely or partially fluorinated vinyl ethers.

Examples of the monomer for imparting a crosslinking group include a (meth)acrylate monomer previously having a crosslinking functional group within the molecule, such as glycidyl methacrylate, and a (meth)acrylate monomer having a carboxyl group, a hydroxy group, an amino group or a sulfonic acid group (e.g., (meth)acrylic acid, methylol(meth)acrylate, hydroxyalkyl(meth)acrylate, allyl acrylate). In the latter case, as disclosed in JP-A-10-25388 and JP-A-10-147739, a crosslinked structure can be introduced after the copolymerization.

The low refractive index layer is not limited to the above-describe copolymer of a fluorine-containing monomer and a monomer for imparting a crosslinking group but may also be a polymer produced by additionally copolymerizing other monomers. The other monomer which can be copolymerized is not particularly limited, but examples thereof include olefins (e.g., ethylene, propylene, isoprene, vinyl chloride, vinylidene chloride), acrylic acid esters (e.g., methyl acrylate, methyl acrylate, ethyl acrylate, 2-ethylhexyl acrylate), methacrylic acid esters (e.g., methyl methacrylate, ethyl methacrylate, butyl methacrylate, ethylene glycol dimethacrylate), styrene derivatives (e.g., styrene, divinylbenzene, vinyltoluene, α-methylstyrene), vinyl ethers (e.g., methyl vinyl ether), vinyl esters (e.g., vinyl acetate, vinyl propionate, vinyl cinnamate), acrylamides (e.g., N-tert-butylacrylamide, N-cyclohexylacrylamide), methacrylamides and acrylonitrile derivatives.

In the fluorine-containing resin used for the low refractive index layer (50), an Si oxide ultrafine particle preferably having an average particle diameter of 0.1 μm or less, more preferably from 0.001 to 0.05 μm, is preferably added for imparting scratch resistance. From the standpoint of enhancing the light extraction efficiency, the refractive index is preferably lower, but when the refractive index of the fluorine-containing resin is lowered, the toughness is worsened. The best balanced point between the scratch resistance and the low refractive index can be found by optimizing the refractive index of the fluorine-containing resin and the amount added of the Si oxide ultrafine particle. As for the Si oxide ultrafine particle, a silica sol dispersed in a commercially available organic solvent may be directly added to the coating solution, or a commercially available silica powder of various types may be dispersed in an organic solvent and used. Also, a further lower refractive index can be realized by using a hollow silica particle containing an air bubble in the Si fine particle.

A preferred embodiment of the above-described light diffusing film is a film comprising a transparent substrate film (20) and a light diffusing layer formed on the transparent substrate film, wherein the light-diffusing layer comprises a transparent resin composition having dispersed therein a light scattering particle differing in the refractive index from the resin composition and the refractive index layer of the resin composition in the light diffusing layer is 1.6 or more. By virtue of this construction, an amount of total reflection in an organic EL emitting layer becomes half or less. In this embodiment, the resin composition for the light diffusing layer preferably contains at least one inorganic fine particle selected from the group consisting of ZrO₂, TiO₂, SnO₂ and ZnO, and by virtue of this construction, the light-transmitting resin layer becomes high refractive index.

In another preferred embodiment of the light diffusing film, the light diffusing film is a film comprising a transparent substrate film and a light diffusing layer formed on the transparent substrate film, wherein the light diffusing layer comprises a transparent resin composition having dispersed therein at least one fine particle selected from the group consisting of ZrO₂, TiO₂, SnO₂ and ZnO, having an average particle diameter of 50 to 300 nm. By virtue of this construction, the light-transmitting resin becomes a high refractive index layer having light scattering property.

### <Transparent Substrate Film>

The material for the transparent substrate film (20) includes a transparent resin film, a transparent resin plate and a transparent resin sheet. Examples of the transparent resin film which can be used include a triacetate cellulose (TAC) film (refractive index: 1.48), a polyethylene terephthalate (PET) film, a diacetylene cellulose film, an acetate butyrate cellulose film, a polyether sulfone film, a polyacrylic resin film, a polyurethane-based resin film, a polyester film, a polycarbonate film, a polysulfone film, a polyether film, a polymethylpentene film, a polyether ketone film and a (meth)acrylonitrile film. The thickness of the transparent substrate film is usually on the order of 25 to 1,000 μm.

### <<Color Filter>>

The color filter for use in the present invention is described in detail below. The color filter can be obtained by curing a curable composition containing a colorant and a light scattering particle, for example, the pattern of each of RGB colors can be formed by applying the curable composition on a transparent substrate or barrier layer and ultraviolet-curing the coating through a mask pattern. The patterns may also be formed using an inkjet method for respective pixels.

### <Curable Composition>

The curable composition for use in the present invention comprises at least an alkali-soluble resin, a light scattering particle, a colorant, a photosensitive polymerization component and a photopolymerization initiator and generally contains a solvent (hereinafter sometimes referred to as an “organic solvent). The curable composition for use in the present invention can be constructed as a negative type by containing the above-described photosensitive polymerization component and photopolymerization initiator and may be constituted to further contain a crosslinking agent or other components for enhancing the curing degree of the film.

### <Colorant>

The colorant which is preferably used in the present invention includes, for example, a particle comprising an organic pigment, an organic coloring matter, a polymer organic material such as fullerene, polydiacetylene and polyimide, or an aromatic or aliphatic hydrocarbon (such as an aromatic or aliphatic hydrocarbon having an orienting property, or an aromatic or aliphatic hydrocarbon having a subliming property). Above all, an organic pigment, an organic coloring matter or a polymer organic material is preferred, and an organic pigment is more preferred. The organic particle may be used singly or in plurality, or a combination of these organic particles may be used.

The organic agent is not limited in terms of color and hue, and examples thereof include perylene, perynone, quinacridone, quinacridonequinone, anthraquinone, anthanthrone, benzimidazolone, condensed disazo, disazo, azo, indanthrone, phthalocyanine, triaryl carbonium, dioxazine, aminoanthraquinone, diketopyrrolopyrrole, thioindigo, isoindoline, isoindolinone, pyranthrone and isoviolanthrone compound pigments, and a mixture thereof.

More specifically, examples thereof include a perylene compound pigment such as C.I. Pigment Red 190 (C.I. No. 71140), C.I. Pigment Red 224 (C.I. No 71127) and C.I. Pigment Violet 29 (C.I. No. 71129); a perynone compound pigment such as C.I Pigment Orange 43 (C.I. No. 71105) and C.I. Pigment Red 194 (C.I. No. 71100); a quinacridone compound pigment such as C.I. Pigment Violet 19 (C.I. No. 73900), C.I. Pigment Violet 42, C.I. Pigment Red 122 (C.I. No. 73915), C.I. Pigment Red 192, C.I. Pigment Red 202 (C.I. No. 73907), C.I. Pigment Red 207 (C.I. Nos. 73900 and 73906) and C.I. Pigment Red 209 (C.I. No. 73905); a quinacridonequinone compound pigment such as C.I. Pigment Red 206 (C.I. No. 73900/73920), C.I. Pigment Orange 48 (C.I. No. 73900/73920) and C.I. Pigment Orange 49 (C.I. No. 73900/73920); an anthraquinone compound pigment such as C.I. Pigment Yellow 147 (C.:. No. 60645); an anthanthrone compound pigment such as C.I. Pigment Red 168 (C.I. No. 59300); a benzimidazolone compound pigment such as C.I. Pigment Brown 25 (C.I. No. 12510), C.I. Pigment Violet 32 (C.I. No. 12517), C.I. Pigment Yellow 180 (C.I. No. 21290), C.I. Pigment Yellow 181 (C.I. No. 11777), C.I. Pigment Orange 62 (C.I. No. 11775) and C.I. Pigment Red 185 (C.I. No. 12516); a condensed disazo compound pigment such as C.I. Pigment Yellow 93 (C.I. No. 20710), C.I. Pigment Yellow 94 (C.I. No. 20038), C.I. Pigment Yellow 95 (C.I. No. 20034), C.I. Pigment Yellow 128 (C.I. No. 20037), C.I. Pigment Yellow 166 (C.I. No. 20035), C.I. Pigment Orange 34 (C.I. No. 21115), C.I. Pigment Orange 13 (C.I. No. 21110), C.I. Pigment Orange 31 (C.I. No. 20050), C.I. Pigment Red 144 (C.I. No. 20735), C.I. Pigment Red 166 (C.I. No. 20730), C.I. Pigment Red 220 (C.I. No. 20055), C.I. Pigment Red 221 (C.I. No. 20065), C.I. Pigment Red 242 (C.I. No. 20067), C.I. Pigment Red 248, C.I. Pigment Red 262 and C.I. Pigment Brown 23 (C.I. No. 20060); a disazo compound pigment such as C.I. Pigment Yellow 13 (C.I. No. 21100), C.I. Pigment Yellow 83 (C.I. No. 21108) and C.I. Pigment Yellow 188 (C.I. No. 21094); an azo compound pigment such as C.I. Pigment Red 187 (C.I. No. 12486), C.I. Pigment Red 170 (C.I. No. 12475), C.I. Pigment Yellow 74 (C.I. No. 11714), C.I. Pigment Yellow 150 (C.I. No. 48545), C.I. Pigment Red 48 (C.I. No. 15865), C.I. Pigment Red 53 (C.I. No. 15585), C.I. Pigment Orange 64 (C.I. No. 12760) and C.I. Pigment Red 247 (C.I. No. 15915); an indanthrone compound pigment such as C.I. Pigment Blue 60 (C.I. No. 69800); a phthalocyanine compound pigment such as C.I. Pigment Green 7 (C.I. No. 74260), C.I. Pigment Green 36 (C.I. No. 74265), C.I. Pigment Green 37 (C.I. No. 74255), C.I. Pigment Blue 16 (C.I. No. 74100), C.I. Pigment Blue 75 (C.I. No. 74160:2), C.I. Pigment Blue 15:6 (C.I. No. 74160) and C.I. Pigment Blue 15:3 (C.I. No. 74160); a triaryl carbonium compound pigment such as C.I. Pigment Blue 56 (C.I. No. 42800) and C.I. Pigment Blue 61 (C.I. No. 42765:1); a dioxazine compound pigment such as C.I. Pigment Violet 23 (C.I. No. 51319) and C.I. Pigment Violet 37 (C.I. No. 51345); an aminoanthraquinone compound pigment such as C.I. Pigment Red 177 (C.I. No 65300); a diketopyrrolopyrrole compound pigment such as C.I. Pigment Red 254 (C.I. No. 56110), C.I. Pigment Red 255 (C.I. No. 561050), C.I. Pigment Red 264, C.I. Pigment Red 272 (C.I. No. 561150), C.I. Pigment Orange 71 and C.I. Pigment Orange 73; a thioindigo compound pigment such as C.I. Pigment Red 88 (C.I. No. 73312); an isoindoline compound pigment such as C.I. Pigment Yellow 139 (C.I. No. 56298), C.I. Pigment Orange 66 (C.I. No. 48210); an isoindolinone compound pigment such as C.I. Pigment Yellow 109 (C.I. No, 56284), C.I. Pigment Yellow 185 (C.I. No. 56290) and C.I. Pigment Orange 61 (C.I. No. 11295); a pyranthrone compound pigment such as C.I. Pigment Orange 40 (C.I. No. 59700) and C.I. Pigment Red 216 (C.I. No. 59710); a quinophthalone-based pigment such as C.I. Pigment Yellow 138, and an isoviolanthrone compound pigment such as C.I. Pigment Violet 31 (C.I. No. 60010). Among these, a quinacridone compound pigment, a diketopyrrolopyrrole compound pigment, a dioxazine compound pigment, a phthalocyanine compound pigment and an azo compound pigment are preferred, and a diketopyrrolopyrrole compound pigment, a dioxazine compound pigment and a phthalocyanine compound pigment are more preferred.

In the curable composition, the total amount of the colorants for use in the present invention is preferably from 20 to 60 mass %, more preferably from 30 to 55 mass %, still more preferably from 35 to 50 mass %, based on the mass in the composition. Incidentally, the ratio of the materials constituting the colorant can be appropriately selected according to the purpose such as color and hue.

When the colorant is used in the form of a powdery processed pigment by finely dispersing it in an acrylic resin, a maleic acid-based resin, a vinyl chloride-vinyl acetate copolymer, an ethyl cellulose resin or the like, a curable composition excellent in the dispersibility and dispersion stability can be obtained.

The method for treating the pigment is described below. In the present invention, the pigment is preferably treated with various resins in advance. That is, the pigment in general is, after the synthesis, dried by various methods and is usually supplied in a powder form by drying it from a water medium, but a large quantity of evaporation latent heat is necessary for the drying of water and a large quantity of heat energy is applied to obtain a dry powder. Accordingly, the pigment usually forms an aggregate (secondary particle) resulting from aggregation of primary particles and since such a pigment as forming an aggregate is not easily dispersed into fine particles, the pigment is preferably treated with a resin in advance. The resin used here includes an alkali-soluble resin described later.

The treating method includes a flushing treatment and a kneading treatment using a kneader, an extruder, a ball mill, a two- or three-roll mill or the like. Of these, a flushing treatment or a kneading method using a two- or three-roll mill is suitable for the fine particle formation.

The flushing treatment is usually a method of mixing a pigment liquid dispersion in water with a resin solution prepared through dissolution in a solvent immiscible with water, extracting the pigment from the water medium into an organic medium, and treating the pigment with a resin. According to this method, the pigment does not pass through drying, so that the pigment can be prevented from aggregation and easily dispersed. The kneading by a two- or three-roll mill is a method of mixing a pigment with a resin or a resin solution, and then kneading the pigment and the resin while applying high shear (searing force) to coat the resin on the pigment surface, thereby treating the pigment. In this process, the aggregated pigment particle is dispersed into from lower order aggregates to primary particles.

The pigment may also be used in the form of a processed pigment previously treated with an acryl resin, a vinyl chloride-vinyl acetate resin, a maleic acid resin, an ethyl cellulose resin, a nitrocellulose resin or the like. This processed pigment is preferably in a powder, paste, pellet or paste form where a resin and a pigment are uniformly dispersed. A non-uniform bulky form resulting from gelling of a resin is not preferred.

For the purpose of enhancing the dispersibility of the pigment, a conventionally known pigment dispersant or surfactant may be used in combination. As for the pigment dispersant or surfactant, there are many kinds of compounds, but examples thereof include a cationic surfactant such as phthalocyanine derivative (EFKA-745, produced by EFKA Additive BV), SOLSPERSE 5000 (produced by Zeneca, Inc.), organosiloxane polymer KP-341 (produced by Shin-Etsu Chemical Co., Ltd.), (meth)acrylic acid-based (co)polymers Polyflow No. 75, No. 90 and No. 95 (produced by Kyoeisha Chemical Co., Ltd.), and W001 (produced by Yusho Co., Ltd.); a nonionic surfactant such as polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and sorbitan fatty acid ester; an anion surfactant such as W004, W005 and W017 (produced by Yusho Co., Ltd.); a polymer dispersant such as EFKA-46, EFKA-47, EFKA-47EA, EFKA Polymer 100, EFKA Polymer 400, EFKA Polymer 401, EFKA Polymer 450 (all produced by Morishita & Co., Ltd.), Disperse Aid 6, Disperse Aid 8, Disperse Aid 15 and Disperse Aid 9100 (produced by San Nopco Ltd.); various SOLSPERSE dispersants such as SOLSPERSE 3000, SOLSPERSE 5000, SOLSPERSE 9000, SOLSPERSE 12000, SOLSPERSE 13240, SOLSPERSE 13940, SOLSPERSE 17000, SOLSPERSE 24000, SOLSPERSE 26000 and SOLSPERSE 28000 (produced by Zeneca, Inc.); Adeka Pluronic L31, Adeka Pluronic F38, Adeka Pluronic L42, Adeka Pluronic L44, Adeka Pluronic L61, Adeka Pluronic L64, Adeka Pluronic F68, Adeka Pluronic L72, Adeka Pluronic P95, Adeka Pluronic F77, Adeka Pluronic P84, Adeka Pluronic F87, Adeka Pluronic P94, Adeka Pluronic L101, Adeka Pluronic P103, Adeka Pluronic F108, Adeka Pluronic L121, Adeka Pluronic P-123 (all produced by ADEKA Corp.), and IONET S-20 (produced by Sanyo Chemical Industries, Ltd.).

### <Alkali-Soluble Resin>

The curable composition for use in the present invention contains at least one alkali-soluble resin. The alkali-soluble resin is not particularly limited but is preferably a linear organic high molecular weight polymer which is soluble in an organic solvent and can be developed with a weakly alkali aqueous solution.

Examples of the linear organic high molecular weight polymer include a polymer having a carboxylic acid in the side chain, such as methacrylic acid copolymer, acrylic acid copolymer, itaconic acid copolymer, crotonic acid copolymer, maleic acid copolymer and partially esterified maleic acid copolymer described in JP-A-59-44615, JP-B-54-34327 (the term “JP-B” as used herein means an “examined Japanese patent publication”), JP-B-58-12577JP-B-54-25957, JP-A-59-53836 and JP-A-59-71048; and an acidic cellulose derivative similarly having a carboxylic acid in the side chain. Other than these, for example, a hydroxyl group-containing polymer to which an acid anhydride is added is also useful.

Among these polymers, a benzyl (meth)acrylate/(meth)acrylic acid copolymer and a multicomponent copolymer comprising benzyl (meth)acrylate/(meth)acrylic acid/other monomers are preferred. In addition, a water-soluble polymer such as 2-hydroxyethyl methacrylate, polyvinylpyrrolidone, polyethylene oxide and polyvinyl alcohol is also useful. Furthermore, in view of the strength of the cured film, an alcohol-soluble nylon and a polyether of 2,2-bis-(4-hydroxyphenyl)-propane and epichlorohydrin are also useful. These polymers may be mixed in arbitrary amounts and used.

Other examples include a 2-hydroxypropyl (meth)acrylate/polystyrene micromonomer/benzyl methacrylate/methacrylic acid copolymer, a 2-hydroxy-3-phenoxypropyl acrylate/polymethyl methacrylate macromonomer/benzyl methacrylate/methacrylic acid copolymer, a 2-hydroxyethyl methacrylate/polystyrene macromonomer/methyl methacrylate/methacrylic acid copolymer, and a 2-hydroxyethyl methacrylate/polystyrene macromonomer/benzyl methacrylate/methacrylic acid copolymer, described in JP-A-7-140654.

The alkali-soluble resin preferred in the present invention is an alkali-soluble resin having a carboxyl group particularly in the side chain. Also, from the standpoint of maintaining good developability after exposure and good coatability, an alkali-soluble resin having an acid value of 30 to 200 is preferred.

As described above, many of alkali-soluble resins in general are an acrylic copolymer using an unsaturated carboxyl acid in its copolymerizable monomer. Above all, an acrylic copolymer having a polyalkylene oxide chain in the side chain is preferred in that the liquid characteristics of a coating solution prepared from the curable composition are improved to less cause a problem of liquid residue in the coating pipeline and furthermore, a thin coating film in a uniform thickness is easily obtained. Particularly, a good coating film can be obtained in a high yield by slit coating which is suitable for the coating on a wide and large-area substrate.

The total amount of the alkali-soluble resins in the curable composition is preferably from 5 to 80 mass %, more preferably from 20 to 60 mass %, based on all solid components. When the total amount is 5 mass % or more, sufficiently high film strength is obtained, and when it is 80 mass % or less, the solubility can be easily controlled because the acidic content does not become excessively large, or a sufficiently high image density can be obtained by virtue of the relatively increased pigment amount.

Also, for enhancing the crosslinking efficiency of the curable composition for use in the present invention, the alkali-soluble resin may have a polymerizable group in the side chain, and, for example, a polymer containing an allyl group, a (meth)acryl group or an allyloxyalkyl group in the side chain is useful. Examples of the polymer containing such a polymerizable group are described below, but the polymer is not limited thereto and may be sufficient if it contains an alkali-soluble group such as COOH group, OH group or ammonium group and a carbon-carbon unsaturated bond.

Specific examples of the polymer which can be used include a compound obtained by reacting a carbon-carbon unsaturated bond group-containing compound having an epoxy ring reactive with an —OH group (for example, a compound such as glycidyl acrylate), and a copolymer of an —OH group-containing monomer such as 2-hydroxyethyl acrylate, a —COOH group-containing monomer such as methacrylic acid and a monomer copolymerizable with these monomers, such as acryl compound or vinyl-based compound. In the reaction with an —OH group, a compound having an acid anhydride, an isocyanate group or an acryloyl group, instead of an epoxy ring, may also be used. Furthermore, a reaction product obtained by reacting an epoxy ring-containing compound with an unsaturated carboxylic acid such as acrylic acid and then reacting the obtained compound with a saturated or unsaturated polybasic acid anhydride, described in JP-A-6-102669 and JP-A-6-1938, may also be used. Examples of the compound having both an alkali-soluble group such as —COOH group and a carbon-carbon unsaturated group include DIANAL NR series (produced by Mitsubishi Rayon Co., Ltd.); Photomer 6173 (—COOH group-containing polyurethane acrylic oligomer, produced by Diamond Shamrock Co., Ltd.); VISCOAT R-264 and KS RESIST 106 (both produced by Osaka Organic Chemical Industry Ltd.); CYCLOMER P series and PLACCEL CF200 series (both produced by Daicel Chemical Industries, Ltd.); and Ebecryl 3800 (produced by Daicel-UCB Company Ltd.).

### <Photosensitive Polymerization Component>

The curable composition of the present invention contains at least one kind of a photosensitive polymerization component. The photosensitive polymerization component is preferably a compound having at least one addition-polymerizable ethylenically unsaturated group and having a boiling point of 100° C. or more under atmospheric pressure, more preferably a tetrafunctional or greater acrylate compound.

Examples of the “compound having at least one addition-polymerizable ethylenically unsaturated group and having a boiling point of 100° C. or more under atmospheric pressure”include a monofunctional acrylate or methacrylate such as polyethylene glycol mono(meth)acrylate, polypropylene glycol mono(meth)acrylate and phenoxyethyl(meth)acrylate; and a polyfunctional acrylate or methacrylate (for example, a compound obtained by adding ethylene oxide or propylene oxide to a polyfunctional alcohol and then (meth)acrylating the adduct, such as polyethylene glycol di(meth)acrylate, trimethylolethane tri(meth)acrylate, neopentyl glycol (meth)acrylate, pentaerythritol tri(meth)acrylate, pentaerythritol tetra(meth)acrylate, dipentaerythritol hexa(meth)acrylate, hexanediol(meth)acrylate, trimethylolpropane tri(acryloyloxyproyl)ether, tri(acryloyloxyethyl)isocyanurate, glycerin and trimethylolethane; a compound obtained by poly(meth)acrylating pentaerythritol or dipentaerythritol; urethane acrylates described in JP-B-48-41708, JP-B-50-6034 and JP-A-51-37193; polyester acrylates described in JP-A-48-64183, JP-B-49-43191 and JP-B-52-30490; and epoxy acrylates which are a reaction product of epoxy resin and (meth)acrylic acid). Furthermore, those set forth as a photocurable monomer or oligomer in Journal of the Adhesion Society of Japan, Vol. 20, No. 7, pp. 300-308 may also be used.

As for the compound obtained by adding ethylene oxide or propylene oxide to a polyfunctional alcohol and then (meth)acrylating the adduct, those represented by formulae (1) and (2) as well as specific examples thereof described in JP A-10-62986 may also be used as the photosensitive polymerization component.

Above all, dipentaerythritol pent(meth)acrylate, dipentaerythritol hexa(meth)acrylate, and a structure where the acryloyl group of such a (meth)acrylate is bonded through an ethylene glycol or propylene glycol residue, are preferred.

An oligomer type may also be suitably used, and an acrylic oligomer having 3 to 20 (preferably 3 to 10) monomer repeating units is preferred.

In the case of using an acrylic oligomer as the photosensitive polymerization component, the polymerization strength is increased by virtue of its high exposure sensitivity, hardly causing separation of the pattern at the development with a developer, and a longer time is allowed as the appropriate development time, that is, the development latitude can be broadened.

One of the photosensitive polymerization components described above may be used alone, or two or more thereof may be used in combination.

### <Photopolymerization Initiator>

The curable composition of the present invention contains at least one kind of a photopolymerization initiator. Examples of the photopolymerization initiator include an active halogen compound such as halomethyloxadiazole and halomethyl-s-triazine, a 3-aryl-substituted coumarin compound, and at least a kind of lophine dimer. In particular, a halomethyl-s-triazine-based compound is preferred. These compounds are described in detail below.

Out of active halogen compounds such as halomethyl-oxadiazole and halomethyl-s-triazine, examples of the halomethyloxadiazole compound includes a 2-halomethyl-5-vinyl-1,3,4-oxadiazole compound. Specific examples thereof include 2-trichloromethyl-5-styryl-1,3,4-oxadiazole, 2-trichloromethyl-5-(p-cyanostyryl)-1,3,4-oxadiazole and 2-trichloromethyl-5-(p-methoxystyryl)-1,3,4-oxadiazole.

Examples of the halomethyl-s-triazine-based compound include a vinyl-halomethyl-s-triazine compound described in JP-B-59-1281; and a 2-(naphth-1-yl)-4,6-bis-halomethyl-s-triazine compound and a 4-(p-aminophenyl)-2,6-di-halomethyl-s-triazine compound described in JP-A-53-133428.

Specific examples of the vinyl-halomethyl-s-triazine compound include 2,4-bis(trichloromethyl)-6-p-methoxystyryl-s-triazine, 2,4-bis(trichloromethyl)-6-(1-p-dimethylaminophenyl-1,3-butadienyl)-s-triazine and 2-trichloromethyl-4-amino-6-p-methoxystyryl-s-triazine.

Specific examples of the 2-(naphth-1-yl)-4,6-bis-halomethyl-s-triazine compound include 2-(naphth-1-yl)-4,6-bis-trichloromethyl-s-triazine, 2-(4-methoxy-naphth-1-yl)-4,6-bis-trichloromethyl-s-triazine, 2-(4-ethoxy-naphth-1-yl)-4,6-bis-trichloromethyl-s-triazine, 2-(4-butoxy-naphth-1-yl)-4,6-bis-trichloromethyl-s-triazine, 2-[4-(2-methoxyethyl)-naphth-1-yl]-4,6-bis-trichloromethyl-s-triazine, 2[4-(2-ethoxyethyl)-naphth-1-yl]-4,6-bis-trichloromethyl-s-triazine, 2-[4-(2-butoxyethyl)-naphth-1-yl]-4,6-bis-trichloromethyl-s-triazine, 2-(2-methoxy-naphth-1-yl)-4,6-bis-trichloromethyl-s-triazine, 2-(6-methoxy-5-methyl-naphth-2-yl)-4,6-bis-trichloromethyl-s-triazine, 2-(6-methoxy-naphth-2-yl)-4,6-bis-trichloromethyl-s-triazine, 2-(5-methoxy-naphth-1-yl)-4,6-bis-trichloromethyl-s-triazine, 2-(4,7-dimethoxy-naphth-1-yl)-4,6-bis-trichloromethyl-s-triazine, 2-(6-ethoxy-naphth-2-yl)-4,6-bis-trichloromethyl-s-triazine, and 2-(4,5-dimethoxy-naphth-1-yl)-4,6-bis-trichloromethyl-s-triazine.

Specific examples of the 4-(p-aminophenyl)-2,6-di-halomethyl-s-triazine compound include 4-[p-N,N-di-(ethoxycarbonylmethyl)aminophenyl]-2,6-di(trichloromethyl)-s-triazine, 4-[o-methyl-p-N,N-di(ethoxycarbonylmethyl)-aminophenyl]-2,6-di(trichloromethyl)-s-triazine, 4-[p-N,N-di(chloroethyl)aminophenyl]-2,6-di(trichloromethyl)-s-triazine, 4-[o-methyl-p-N,N-di(chloroethyl)aminophenyl]-2,6-di(trichloromethyl)-s-triazine, 4-(p-N-chloroethyl-aminophenyl)-2,6-di(trichloromethyl)-s-triazine, 4-(p-N-ethoxycarbonylmethylaminophenyl)-2,6-di(trichloromethyl)-s-triazine, 4-[p-N,N-di(phenyl)aminophenyl]-2,6-di(trichloro-methyl)-s-triazine, 4-(p-N-chloroethylcarbonylaminophenyl)-2,6-di(trichloromethyl)-s-triazine, 4-[p-N-(p-methoxy-phenyl)carbonylaminophenyl]-2,6-di(trichloromethyl)-s-triazine, 4-[m-N,N-di(ethoxycarbonylmethyl)aminophenyl]-2,6-di(trichloromethyl)-s-triazine,

4-[m-bromo-p-N,N-di(ethoxycarbonylmethyl)aminophenyl]-2,6-di(trichloromethyl)-s-triazine, 4-[m-chloro-p-N,N-di(ethoxycarbonylmethyl)aminophenyl]-2,6-di(trichloromethyl)-s-triazine, 4-[m-fluoro-p-N,N-di(ethoxycarbonyl-methyl)aminophenyl]-2,6-di(trichloromethyl)-s-triazine, 4-[o-bromo-p-N,N-di(ethoxycarbonylmethyl)aminophenyl]-2,6-di(trichloromethyl)-s-triazine, 4-[o-chloro-p-N,N-di-(ethoxycarbonylmethyl)aminophenyl]-2,6-di(trichloromethyl)-s-triazine, 4 [o-fluoro-p-N,N-di(ethoxycarbonylmethyl)-aminophenyl]-2,6-di(trichloromethyl)-s-triazine, 4-[o-bromo-p-N,N-di(chloroethyl)aminophenyl]-2,6-di(trichloromethyl)-s-triazine, 4-[o-chloro-p-N,N-di(chloroethyl)aminophenyl]-2,6-di(trichloromethyl)-s-triazine,

4-[o-fluoro-p-N,N-di(chloroethyl)aminophenyl]-2,6-di(trichloromethyl)-s-triazine, 4-[m-bromo-p-N,N-di(chloro-ethyl)aminophenyl]-2,6-di(trichloromethyl)-s-triazine, 4-[m-chloro-p-N,N-di(chloroethyl)aminophenyl]-2,6-di(tri-chloromethyl)-s-triazine, 4-[m-fluoro-p-N,N-di(chloro-ethyl)aminophenyl]-2,6-di(trichloromethyl)-s-triazine, 4-(m-bromo-p-N-ethoxycarbonylmethylaminophenyl)-2,6-di(tri-chloromethyl)-s-triazine, 4-(m-chloro-p-N-ethoxycarbonyl-methylaminophenyl)-2, 6-di(trichloromethyl)-s-triazine, 4-(m-fluoro-p-N-ethoxycarbonylmethylaminophenyl)-2,6-di(tri-chloromethyl)-s-triazine, 4-(o-bromo-p-N-ethoxycarbonyl-methylaminophenyl)-2,6-di(trichloromethyl)-s-triazine,

4-(o-chloro-p-N-ethoxycarbonylmethylaminophenyl)-2,6-di(trichloromethyl)-s-triazine, 4-(o-fluoro-p-N-ethoxy-carbonylmethylaminophenyl)-2,6-di(trichloromethyl)-s-triazine, 4-(m-bromo-p-N-chloroethylaminophenyl)-2,6-di(tri-chloromethyl)-s-triazine, 4-(m-chloro-p-N-chloroethylaminophenyl)-2,6-di(trichloromethyl)-s-triazine, 4-(m-fluoro-p-N-chloroethylaminophenyl)-2,6-di(trichloromethyl)-s-triazine, 4-(o-bromo-p-N-chloroethylaminophenyl)-2,6-di(trichloromethyl)-s-triazine, 4-(o-chloro-p-N-chloroethylaminophenyl)-2,6-di(trichloromethyl)-s-triazine, and 4-(o-fluoro-p-N-chloroethylaminophenyl)-2,6-di(trichloromethyl)-s-triazine.

A sensitizer may be used in combination with the photopolymerization initiator. Specific examples thereof include benzoin, benzoin methyl ether, 9-fluorenone, 2-chloro-9-fluorenone, 2-methyl-9-fluorenone, 9-anthrone, 2-bromo-9-anthrone, 2-ethyl-9-anthrone, 9,10-anthraquinone, 2-ethyl 9,10-anthraquinone, 2-tert-butyl-9,10-anthraquinone, 2,6-dichloro-9,10-anthraquinone, xanthone, 2-methylxanthone, 2-methoxyxanthone, 2-methoxyxanthone, thioxanthone, benzyl, dibenzalacetone, p-(dimethylamino)phenyl styryl ketone, p-(dimethylamino)phenyl-p-methyl styryl ketone, benzophenone, p-(dimethylamino)benzophenone (or Michler's ketone), p-(diethylamino)benzophenone and benzanthrone, and further include a benzothiazole-based compound described in JP-B-51-48516.

In regard to the 3-aryl-substituted coumarin compound as the photopolymerization initiator, {(s-triazin-2-yl)amino}-3-arylcoumarin compounds are preferred.

The lophine dimer as the photopolymerization initiator means a 2,4,5-triphenylimidazolyl dimer comprising two lophine residues, and specific examples thereof include a 2-(o-chlorophenyl)-4,5-diphenylimidazolyl dimer, a 2-(o-fluorophenyl)-4,5-diphenylimidazolyl dimer, a 2-(o-methoxyphenyl)-4,5-diphenylimidazolyl dimer, a 2-(p-methoxyphenyl)-4,5-diphenylimidazolyl dimer, a 2-(p-dimethoxyphenyl)-4,5-diphenylimidazolyl dimer, a 2(2,4 dimethoxyphenyl)-4,5-diphenylimidazolyl dimer, and a 2-(p-methylmercaptophenyl)-4,5-diphenylimidazolyl dimer.

In the present invention, known compounds other than the photopolymerization initiators described above can also be used. Examples thereof include a vicinal polyketol aldonil compound described in U.S. Pat. No. 2,367,660, an α-carbonyl compound described in U.S. Pat. Nos. 2,367,661 and 2,367,670, an acyloin ether described in U.S. Pat. No. 2,448,828, an α-hydrocarbon-substituted aromatic acyloin compound described in U.S. Pat. No. 2,722,512, a polynuclear quinone compound described in U.S. Pat. Nos. 3,046,127 and 2,951,758, a combination of triallylimidazole dimer/p-aminophenyl ketone described in U.S. Pat. No. 3,549,367, and a benzothiazole-based compound/a trihalomethyl-s-triazine compound described in JP-B-51-48516. Also, ADEKA OPTOMER SP-150, ADEKA OPTOMER SP-151, ADEKA OPTOMER SP-170, ADEKA OPTOMER SP-171, ADEKA OPTOMER N-1717, ADEKA OPTOMER N1414 and the like produced by ADEKA Corp. may be used as the polymerization initiator.

The content of the photopolymerization initiator in the curable composition is preferably from 0.1 to 10.0 mass %, more preferably from 0.5 to 5.0 mass %, based on the entire solid content of the composition. When this content is 0.1 mass % or more, the polymerization readily proceeds without fail, and when it is 10.0 mass % or less, sufficiently high film strength can be obtained.

### <Solvent>

The curable composition of the present invention is generally prepared using a solvent (in the context of the present invention, sometimes referred to as an “organic solvent”). The solvent is fundamentally not limited in particular as long as it satisfies the solubility of each component and the coatability of the curable composition, but the solvent is preferably selected taking into consideration particularly the solubility, coatability and safety of colorant and resin components.

Preferred examples of the solvent include esters such as ethyl acetate, n-butyl acetate, isobutyl acetate, amyl formate, isoamyl acetate, isobutyl acetate, butyl propionate, isopropyl butyrate, ethyl butyrate, butyl butyrate, alkyl esters, methyl lactate, ethyl lactate, methyl oxyacetate, ethyl oxyacetate, butyl oxyacetate, methyl methoxyacetate, ethyl methoxyacetate, butyl methoxyacetate, methyl ethoxyacetate, and ethyl ethoxyacetate;

3-oxypropionic acid alkyl esters such as methyl 3-oxypropionate and ethyl 3-oxypropionate, e.g., methyl 3-methoxypropionate, ethyl 3-methoxypropionate, methyl 3-ethoxypropionate, ethyl 3-ethoxypropionate; 2-oxypropionic acid alkyl esters such as methyl 2-oxypropionate, ethyl 2-oxypropionate and propyl 2-oxypropionate, e.g., methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, ethyl 2-ethoxy-2-methylpropionate; methyl pyruvate, ethyl pyruvate, propyl pyruvate, methyl acetoacetate, ethyl acetoacetate, methyl 2-oxobutanoate, and ethyl 2-oxobutanoate;

ethers such as diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol methyl ether, propylene glycol methyl ether acetate, propylene glycol ethyl ether acetate, and propylene glycol propyl ether acetate;

ketones such as methyl ethyl ketone, cyclohexanone, 2-heptanone, and 3-heptanone; and aromatic hydrocarbons such as toluene and xylene.

Among these, preferred are methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether, and propylene glycol methyl ether acetate. One of these solvents may be used alone, or two or more thereof may be used in combination.

### <Various Additives>

In the curable composition of the present invention, various additives such as filler, polymer compound except for those described above, surfactant, adhesion accelerator, antioxidant, ultraviolet absorbent and aggregation inhibitor, may be blended, if desired.

Specific examples of these additives include a filler such as glass and alumina; an itaconic acid copolymer, a crotonic acid copolymer, a maleic acid copolymer, a partially esterified maleic acid copolymer, an acidic cellulose derivative, a hydroxyl group-containing polymer added with an acid anhydride, an alcohol-soluble nylon, and an alkali-soluble resin such as phenoxy resin formed from bisphenol A and epichlorohydrin; a nonionic, cationic or anionic surfactant, specifically, a cationic surfactant such as phthalocyanine derivative (e.g., EFKA-745, produced by Morishita & Co., Ltd.), organosiloxane polymer KP341 (produced by Shin-Etsu Chemical Co., Ltd.), (meth)acrylic acid polymers Polyflow No. 75, Polyflow No. 90 and Polyflow No. 95 (produced by Kyoeisha Chemical Co., Ltd.), and W001 (produced by Yusho Co., Ltd.), a nonionic surfactant such as polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate and sorbitan fatty acid ester (e.g., Pluronic L10, Pluronic L31, Pluronic L61, Pluronic L62, Pluronic 10R5, Pluronic 17R2, Pluronic 25R2, Tetronic 304, Tetronic 701, Tetronic 704, Tetronic 901, Tetronic 904 and Tetronic 150R1, all produced by BASF), a fluorine-containing surfactant such as Eftop EF301, Eftop EF303, Eftop EF352 (all produced by Shin Akita Kasei Co., Ltd.), MEGAFACE F-141, MEGAFACE F-142, MEGAFACE F-143 and MEGAFACE F-144 (all produced by DIC Corporation), and an anionic surfactant such as W004, W005 and W017 (produced by Yusho Co., Ltd.); a polymer dispersant such as EFKA-46, EFKA 47, EFKA-47EA, EFKA Polymer 100, EFKA Polymer 400, EFKA Polymer 401, EFKA Polymer 450 (all produced by Morishita & Co., Ltd.), Disperse Aid 6, Disperse Aid 8, Disperse Aid 15 and Disperse Aid 9100 (produced by Sari Nopco Ltd.); various SOLSPERSE dispersants such as SOLSPERSE 3000, SOLSPERSE 5000, SOLSPERSE 9000, SOLSPERSE 12000, SOLSPERSE 13240, SOLSPERSE 13940, SOLSPERSE 17000, SOLSPERSE 24000, SOLSPERSE 26000 and SOLSPERSE 28000 (produced by Zeneca, Inc.); Adeka Pluronic L31, Adeka Pluronic F38, Adeka Pluronic L42, Adeka Pluronic L44, Adeka Pluronic L61, Adeka Pluronic L64, Adeka Pluronic F68, Adeka Pluronic L72, Adeka Pluronic P95, Adeka Pluronic F77, Adeka Pluronic P84, Adeka Pluronic F87, Adeka Pluronic P94, Adeka Pluronic L101, Adeka Pluronic P103, Adeka Pluronic F108, Adeka Pluronic L121, Adeka Pluronic P-123 (all produced by ADEKA Corp.), and IONET S-20 (produced by Sanyo Chemical Industries, Ltd.);

an adhesion accelerator such as vinyltrimethoxysilane, vinyltriethoxysilane, vinyltris(2-methoxyethoxy)silane, N-2 aminoethyl)-3-aminopropylmethyldimethoxysilane, N-(2-aminoethyl)-3-aminopropyltrimethoxysilane, 3-aminopropyl-triethoxysilane, 3-glycidoxypropyltrimethoxysilane, 3-glycidoxypropylmethyldimethoxysilane, 2-(3,4-epoxy-cyclohexyl)ethyltrimethoxysilane, 3-chloropropylmethyl-dimethoxysilane, 3-chloropropyltrimethoxysilane, 3-methacryloxypropyltrimethoxysilane, and 3-mercapto-propyltrimethoxysilane; an antioxidant such as 2,2-thiobis(4-methyl-6-tert-butylphenol) and 2,6-di-tert-butylphenol; an ultraviolet absorbent such as 2-(3-tert-butyl-5-methyl-2-hydroxyphenyl)-5-chlorobenzotriazole and alkoxybenzophenone; and an aggregation inhibitor such as sodium polyacrylate.

Furthermore, in the case of accelerating the alkali solubility of a non-image area and more enhancing the developability of the curable composition of the present invention, an organic carboxylic acid, preferably a low-molecular weight organic carboxylic acid having a molecular weight of 1,000 or less, may be added to the composition. Specific examples thereof include an aliphatic monocarboxylic acid such as formic acid, acetic acid, propionic acid, butyric acid, valeric acid, pivalic acid, caproic acid, diethylacetic acid, enanthic acid, and caprylic acid; an aliphatic dicarboxylic acid such as oxalic acid, malonic acid, succinic acid, glutaric acid, adipic acid, pimelic acid, suberic acid, azelaic acid, sebacic acid, brassylic acid, methylmalonic acid, ethylmalonic acid, dimethylmalonic acid, methylsuccinic acid, tetramethylsuccinic acid, and citraconic acid; an aliphatic tricarboxylic acid such as tricarballylic acid, aconitic acid, and camphoronic acid; an aromatic monocarboxylic acid such as benzoic acid, toluic acid, cuminic acid, hemellitic acid, and mesitylenic acid; an aromatic polycarboxylic acid such as phthalic acid, isophthalic acid, terephthalic acid, trimellitic acid, trimesic acid, mellophanic acid, and pyromellitic acid; and other carboxylic acids such as phenylacetic acid, hydratropic acid, hydrocinnamic acid, mandelic acid, phenylsuccinic acid, atropic acid, cinnamic acid, methyl cinnamate, benzyl cinnamate, cinnamylidene acetic acid, coumaric acid, and unbellic acid.

In addition to these additives, a thermal polymerization inhibitor is preferably added to the curable composition of the present invention, and useful examples thereof include hydroquinone, p-methoxyphenol, di-tert-butyl-p-cresol, pyrogallol, tert-butyl-catechol, benzoquinone, 4,4′-thiobis(3-methyl-6-tert-butylphenol), 2,2′-methylenebis(4-methyl-6-tert-butylphenol), and 2-mercaptobenzimidazole.

### <Light Scattering Particle>

The light scattering particle constituting the curable composition for use in the present invention is not limited in its kind and may be an organic fine particle or an inorganic fine particle. Examples of the organic fine particle include a polymethyl methacrylate bead, an acryl-styrene copolymer bead, a melamine bead, a polycarbonate bead, a styrene bead, a crosslinked polystyrene bead, a polyvinyl chloride bead, and a benzoguanamine-melamine formaldehyde bead. Examples of the inorganic fine particle include SiO₂, ZrO₂, TiO₂, Al₂O₃, In₂O₃, ZnO, SnO₂ and Sb₂O₃. The light scattering particle is preferably at least one fine particle selected from the group consisting of ZrO₂, TiO₂, SnO₂ and ZnO, having an average particle diameter of 50 to 300 nm, because by virtue of this construction, the light-transmitting resin becomes a high refractive index layer having light scattering property.

The cured product of the curable composition fox use in the present invention preferably has a refractive index of 1.6 or more and in this case, an amount of total reflection in an organic EL emitting layer becomes half or less.

Also, the curable composition preferably contains at least one inorganic fine particle selected from the group consisting of ZrO₂, TiO₂, SnO₂ and ZnO, because by virtue of this construction, the light-transmitting resin layer becomes a high refractive index layer.

In the curable composition, the refractive index of the light scattering particle is preferably 1.55 or less, because by virtue of this construction, sufficient scattering amount can be obtained.

Furthermore, in the curable composition, the average diameter of the light scattering particle is preferably from 0.1 to 2.0 μm, because by virtue of this construction, a scattering amount can be sufficiently obtained and the directional characteristics of light scattering become almost isotropic scattering. By making the directional characteristics close to isotropic scattering, more amount of light can be extracted.

The curable composition of the present invention can be generally prepared by mixing a light scattering particles a colorant, an alkali-soluble resin, a photosensitive polymerization component, a photopolymerization initiator and, if desired, various additives with a solvent, and mixing and dispersing the blend by using a mixer or disperser of various types.

For example, the curable composition can be suitably produced as follows. That is, in the production of the curable composition for use in the present invention, a surface modifier or disperser, an alkali-soluble resin and a solvent are mixed with a colorant, and the mixture is kneaded/dispersed. The device used for kneading/dispersion is a two-roll mill, a three-roll mill, a ball mill, a disper, a kneader, a homogenizer, a blender or the like, and the dispersion is performed while applying a strong shearing force. To this kneaded dispersion, a photosensitive polymerization component and a photopolymerization initiator are added and, if desired, a solvent, a dispersant, an alkali-soluble resin, a light scattering particle and other components are further added. These components are finely dispersed by using mainly a sand grinder, a pin mill, a slit mill, an ultrasonic disperser or the like and using, as the dispersion medium, a bead made of glass, zirconia or the like having a particle diameter of 0.1 to 10 mm. Incidentally, the kneading/dispersion treatment may be omitted. In this case, a colorant, a dispersant or surface treating agent, an alkali-soluble resin and a solvent are subjected to a fine dispersion treatment.

Details of kneading/dispersion are described also in T. C. Patton, Paint Flow and Pigment Dispersion, John Wiley and Sons (1964) and the like.

### <Preparation Method of Color Filter>

The color filter for use in the present invention can be prepared by coating the above-described curable composition on a transparent substrate or barrier layer and ultraviolet-curing the coating through a mask pattern, thereby forming a pattern of each of RGB colors. The patterns may also be formed using an inkjet method for respective pixels. In the following, a method of preparing a color filter by coating the curable composition on a substrate, on the upper electrode of an organic EL, or on the barrier layer of an organic EL is described in detail.

The color filter for use in the present invention is prepared using at least three kinds of curable compositions differing in the colorant composition. Out of these three kinds of curable compositions, any one curable composition is coated on a substrate, exposed through a mask and developed to form pixels in the first color. After the formation of pixels in the first color, other one curable composition selected from those colored curable compositions, which is different in the color and hue from the pixels in the first color, is coated on the substrate, exposed through a mask and developed to form pixels in the second color. Furthermore, after the formation of pixels in the second color, other one curable composition selected from those colored curable compositions, which is different in the color and hue from the first and second colors, is coated on the substrate, exposed through a mask and developed to form pixels in the third color, whereby the color filter is obtained. The color filter may also be constructed to have four or more colors by further forming pixels in addition to the first to third colors (for example, green, red and blue).

That is, using at least three kinds of the curable compositions for use in the present invention in a desired order of colors, a step of coating a curable composition on a substrate by a coating method such as spin coating, cast coating or roll coating, drying the coating to form a radiation-sensitive layer, exposing the layer through a predetermined mask pattern, and developing the layer after exposure with a developer to form pixels in a desired pattern is repeated at least three times according to the number of colored compositions, whereby the color filter can be obtained. At this time, a step of curing the formed pixels by means of heating and/or exposure may be provided, if desired. This exposure may be effected by irradiating radiation. The radiation used here is preferably an ultraviolet ray such as g-line, h-line or i-line.

Examples of the substrate constituting the color filter include soda glass used for liquid crystal display devices and the like, Pyrex® glass, quartz glass and those obtained by attaching a transparent electrically conductive film to such a glass. Also, the color filter may be constructed after previously forming a low refractive index layer on such a substrate. Furthermore, the color filter may be constructed directly on the upper electrode or barrier layer constituting an organic EL device. In some cases, black stripes for isolating individual pixels are formed on the substrate.

As for the developer, any developer may be used as long as it dissolves the uncured part of the curable composition for use in the present invention and does not dissolve the cured part. Specifically, a combination of various organic solvents or an alkaline aqueous solution may be used. Examples of the organic solvent include the above-described solvents which are used in preparing the curable composition for use in the present invention.

The alkaline aqueous solution is suitably an alkaline aqueous solution where an alkaline compound such as sodium hydroxide, potassium hydroxide, sodium carbonate, sodium silicate, sodium metasilicate, aqueous ammonia, ethylamine, diethylamine, dimethylethanolamine, tetramethylammonium hydroxide, tetraethylammonium hydroxide, choline, pyrrole or piperidine is dissolved to a concentration of 0.001 to 10 mass %, preferably from 0.01 to 1 mass %. In the case of using a developer comprising such an alkaline aqueous solution, the coating is generally washed with water after development.

### <<Organic Electroluminescent Display Device>>

The light-emitting display device of the present invention is a display device where a light-emitting layer or a plurality of organic compound thin films including a light-emitting layer are formed between a pair of electrodes, that is, an anode and a cathode, and may have a hole injection layer, a hole transport layer, an electron injection layer, an electron transport layer, a protective layer and the like, in addition to the light-emitting layer, and these layers each may have other functions. For the formation of each layer, various materials can be used.

The anode supplies a hole to the hole injection layer, hole transport layer, light-emitting layer or the like, and the material which can be used for the anode is a metal, an alloy, a metal oxide, an electrically conductive compound, a mixture thereof or the like, preferably a material having a work function of 4 eV or more. Specific examples thereof include an electrically conductive metal oxide such as tin oxide, zinc oxide, indium oxide and indium tin oxide (ITO), a metal such as gold, silver, chromium and nickel, a mixture or laminate of such a metal and such an electrically conductive metal oxide, an inorganic electrically conductive substance such as copper iodide and copper sulfide, an organic electrically conductive material such as polyaniline, polythiophene and polypyrrole, and a laminate of such a material with ITO. An electrically conductive metal oxide is preferred, and ITO is more preferred in view of productivity, high electrical conductivity, transparency and the like. The film thickness of the anode may be appropriately selected according to the material, but usually, the film thickness is preferably from 10 nm to 5 μm, more preferably from 50 nm to 1 μm, still more preferably from 100 to 500 nm.

The anode is usually used as a layer formed on soda lime glass, non-alkali glass, a transparent resin substrate or the like. In the case of using glass, the material thereof is preferably non-alkali glass so as to reduce ion dissolved out from the glass. In the case of using soda lime glass, this is preferably used after applying thereto a barrier coat such as silica. The thickness of the substrate is not particularly limited as long as it is sufficiently large to maintain the mechanical strength, but in the case of using glass, the thickness is usually 0.2 mm or more, preferably 0.7 mm or more.

A barrier film may also be used as the transparent resin substrate. The barrier film is a film produced by providing a gas-impermeable barrier layer on a plastic support. Examples of the barrier film include those where silicon oxide or aluminum oxide is vapor-deposited (see, JP-B-53-12953 (the term “JP-B” as used herein means an “examined Japanese patent publication”) and JP-A-58-217344), an organic-inorganic hybrid coating layer is provided (see, JP-A-2000-323273 and JP-A-2004-25732), an inorganic layered compound is provided (see, JP-A-2001-205743), an inorganic material is stacked (see, JP-A-2003-206361 and JP-A-2006-263989), an organic layer and an inorganic layer are alternately stacked (see, JP-A-2007-30387, U.S. Pat. No. 6,413,645, and Affinito et al., Thin Solid Films, pp. 290-291 (1996)), or an organic layer and an inorganic layer are continuously stacked (see, U.S. Pat. No. 2004-46497).

In the production of the anode, various methods are employed according to the material. For example, in the case of ITO, examples of the film formation method include an electron beam method, a sputtering method, a resistance heating vapor deposition method, a chemical reaction method (e.g., sol-gel method), and a method of coating an indium tin oxide dispersion. When the anode is subjected to cleaning or other treatments, this enables decreasing the driving voltage or improving the light emission efficiency of the display device. For example, in the case of ITO, a UV-ozone treatment or the like is effective.

The cathode supplies an electron to the electron injection layer, electron transport layer, light-emitting layer or the like, and the material therefor is selected by taking into consideration the adhesion to a layer adjacent to the negative electrode, such as electron injection layer, electron transport layer or light-emitting layer, the ionization potential, the stability and the like. As for the cathode material, a metal, an alloy, a metal oxide, an electrically conductive compound or a mixture thereof can be used, and specific examples of the material include an alkali metal (e.g., Li, Na, K) or a fluoride thereof, an alkaline earth metal (e.g., Mg, Ca) or a fluoride thereof, gold, silver, lead, aluminum, an alloy or mixed metal of sodium and potassium, an alloy or mixed metal of lithium and aluminum, an alloy or mixed metal of magnesium and silver, and a rare earth metal such as indium and ytterbium. Among these, preferred is a material having a work function of 4 eV or less, and more preferred are aluminum, an alloy or mixed metal of lithium and aluminum, and an alloy or mixed metal of magnesium and silver. The film thickness of the cathode may be appropriately selected according to the material, but usually, the film thickness is preferably from 10 nm to 5 μm, more preferably from 50 nm to 1 μm, still more preferably from 100 nm to 1 μm. Examples of the production method of the cathode include an electron beam method, a sputtering method, a resistance heating vapor deposition method and a coating method, and a single metal component may be vapor-deposited or two or more components may be simultaneously vapor-deposited. Furthermore, an alloy electrode may also be formed by simultaneously vapor-depositing a plurality of metals, or an alloy previously prepared may be vapor-deposited.

The sheet resistance of the anode and cathode is preferably lower and is preferably several hundreds of Ω/sq or less.

The invasion of a gas can be prevented not only by laminating the above-described barrier film on the cathode but also by forming a protective layer on the display surface.

The material for the light-emitting layer may be any material as long as it can form a layer having a function of, when an electric field is applied, injecting a hole from the anode, hole injection layer or hole transport layer and at the same time, injecting an electron from the cathode, electron injection layer or electron transport layer, a function of moving the injected electric charge, or a function of providing a site for the recombination of a hole and an electron to effect light emission. Preferably, the light-emitting layer contains the compound of the present invention, but a light-emitting material other than the compound of the present invention may also be used. Examples thereof include various metal complexes as typified by a metal complex or rare earth complex of benzoxazole derivatives, benzimidazole derivatives, benzothiazole derivatives, styrylbenzene derivatives, polyphenyl derivatives, diphenylbutadiene derivatives, tetraphenylbutadiene derivatives, naphthalimide derivatives, coumarin derivatives, perylene derivatives, perynone derivatives, oxadiazole derivatives, aldazine derivatives, pyralidine derivatives, cyclopentadiene derivatives, bisstyrylanthracene derivatives, quinacridone derivatives, pyrrolopyridine derivatives, thiadiazolopyridine derivatives, cyclopentadiene derivatives, styrylamine derivatives, aromatic dimethylidine compound or 8-quinolinol derivatives; and a polymer compound such as polythiophene, polyphenylene and polyphenylenevinylene. The film thickness of the light-emitting layer is not particularly limited but usually, the thickness is preferably from 1 nm to 5 μm, more preferably from 5 nm to 1 μm, still more preferably from 10 to 500 nm.

The method for forming the light-emitting layer is not particularly limited, but examples of the method include a resistance heating vapor deposition method, an electron beam method, a sputtering method, a molecular lamination method, a coating method (e.g., spin coating, casting, dip coating) and an LB method. A resistance heating vapor deposition method and a coating method are preferred.

The material for the hole injection layer and hole transport layer may be sufficient if it has any one of a function of injecting a hole from the anode, a function of transporting a hole, and a function of blocking the electron injected from the cathode. Specific examples of the material include a carbazole derivative, a triazole derivative, an oxazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydrazone derivative, a stilbene derivative, a silazane derivative, an aromatic tertiary amine compound, a styrylamine compound, an aromatic dimethylidine-based compound, a porphyrin-based compound, a polysilane-based compound, a poly(N-vinylcarbazole) derivative, an aniline-based copolymer, and an electrically conductive polymer or oligomer such as thiophene oligomer and polythiophene. The film thickness of the hole injection layer and hole transport layer is not particularly limited but usually, the thickness is preferably from 1 nm to 5 μm, more preferably from 5 nm to 1 μm, still more preferably from 10 to 500 nm. The hole injection layer and the hole transport layer each may have a single-layer structure comprising one species or two or more species of the above-described materials or may have a multilayer structure comprising a plurality of layers having the same composition or different compositions.

As for the method of forming the hole injection layer and hole transport layer, a vacuum vapor deposition method, an LB method, or a method of dissolving or dispersing the above-described hole injection/transport material in a solvent and coating the obtained solution (e.g., spin coating, casting, dip coating) is used. In the case of a coating method, the material can be dissolved or dispersed together with a resin component, and examples of the resin component include polyvinyl chloride, polycarbonate, polystyrene, polymethyl methacrylate, polybutyl methacrylate, polyester, polysulfone, polyphenylene oxide, polybutadiene, poly(N-vinylcarbazole), hydrocarbon resin, ketone resin, phenoxy resin, polyamide, ethyl cellulose, vinyl acetate, ABS resin, polyurethane, melamine resin, unsaturated polyester resin, alkyd resin, epoxy resin and silicon resin.

The material for the electron injection layer and electron transport layer may be sufficient if it has any one of a function of injecting an electron from the cathode, a function of transporting an electron, and a function of blocking the hole injected from the anode. Specific examples of the material include various metal complexes as typified by a metal complex of triazole derivatives, oxazole derivatives, oxadiazole derivatives, fluorenone derivatives, anthraquinodimethane derivatives, anthrone derivatives, diphenylquinone derivatives, thiopyran dioxide derivatives, carbodiimide derivatives, fluorenylidenemethane derivatives, distyrylpyrazine derivatives, heterocyclic tetracarboxylic acid anhydride (e.g., naphthaleneperylene), phthalocyanine derivatives or 8-quinolinol derivatives, and a metal complex in which the ligand is metal phthalocyanine, benzoxazole or benzothiazole. The film thickness of the electron injection layer and electron transport layer is not particularly limited but usually, the thickness is preferably from 1 nm to 5 μm, more preferably from 5 nm to 1 μm, still more preferably from 10 to 500 nm. The electron injection layer and the electron transport layer each may have a single-layer structure comprising one species or two or more species of the above-described materials or may have a multilayer structure comprising a plurality of layers having the same composition or different compositions.

Examples of the method for forming the electron injection layer and electron transport layer include a vacuum vapor deposition method, an LB method, and a method of dissolving or dispersing the above-described electron injection/transport material in a solvent and coating the obtained solution (e.g., spin coating, casting, dip coating). In the case of a coating method, the material can be dissolved or dispersed together with a resin component, and as regards the resin component, for example, those described above for the hole injection/transport layer can be applied.

The material for the protective layer is sufficient if it has a function of blocking a material which accelerates deterioration of the display device, such as water and oxygen, from intruding into the display device. Specific examples thereof include a metal such as In, Sn, Pb, Au, Cu, Ag, Al, Ti and Ni, a metal oxide such as MgO, SiO, SiO₂, Al₂O₃, GeO, NiO, CaO, BaO, Fe₂O₃, Y₂O₃ and TiO₂, a metal fluoride such as MgF₂, LiF, AlF₃ and CaF₂, polyethylene, polypropylene, polymethyl methacrylate, polyimide, polyurea, polytetrafluoroethylene, polychlorotrifluoroethylene, polydichlorofluoroethylene, a copolymer of chlorotrifluoroethylene and dichlorodifluoroethylene, a copolymer obtained by copolymerizing a monomer mixture containing tetrafluoroethylene and at least one comonomer, a fluorine-containing copolymer having a cyclic structure in the copolymer main chain, a water-absorbing substance having a water absorption percentage of 1% or more, and a moisture-resistant substance having a water absorption percentage of 0.1% or less.

The method for forming the protective layer is also not particularly limited, and examples of the method which can be applied include a vacuum vapor deposition method, a sputtering method, a reactive sputtering method, an MBE (molecular beam epitaxy) method, a cluster ion beam method, an ion plating method, a plasma polymerization method (high frequency-excited ion plating method), a plasma CVD method, a laser CVD method, a heat CVD method, a gas source CVD method, and a coating method.

### <Lamination Method of Light Diffusing Film>

The method for providing the light diffusing film or color filter of the present invention in an organic display includes a method of laminating the light diffusing film or color filter directly on the light extraction-side electrode or barrier layer of an organic EL by using an adhesive or a self-adhesive agent. That is, in one embodiment of the organic electroluminescent display device of the present invention, the scattering member is laminated directly on the upper electrode.

In another embodiment of the organic electroluminescent display device of the present invention, the scattering member is laminated on the upper electrode through a barrier layer or laminated directly on the barrier layer.

In the case where the scattering member is a light diffusing film, the preferred embodiment of the organic electroluminescent display device of the present invention includes an embodiment where the light diffusing film is laminated on the upper electrode or the barrier layer provided on the upper electrode, through an adhesion layer.

### <Adhesive>

The refractive index of the adhesion layer composed of an adhesive is preferably equal to or greater than that of the organic layer. If the refractive index is excessively large, the efficiency decreases due to reflection at the interface. Therefore, the difference in the refractive index from the organic layer is preferably 0.2 or less. In other words, the refractive index of the adhesion layer is preferably 1.6 or more, more preferably from 1.60 to 2.00, because an amount of total reflection in an organic EL emitting layer becomes half or less. As another method for suppressing reflection at the interface, there may be used a method of creating a refractive index gradation in the adhesion layer to allow for bonding of the adhesive and the material at both ends of the adhesive without discontinuity in the refractive index.

The adhesive is preferably an adhesive which flows under heating or pressure, more preferably an adhesive which exhibits flowability under heating at 200° C. or less or under pressure of 1 kgf/cm² or more. By using such an adhesive, the light diffusing film for use in the present invention can be adhered to an adherend, that is, a display or plastic plate, by fluidizing the adhesive. The adhesive can be fluidized, so that an optical film can be easily adhered to an adherend by lamination or pressing, particularly pressing, or even to an adherend having a curved surface or a complicated shape. To this end, the softening temperature of the adhesive is preferably 200° C. or less. Considering usage of the optical film, the use environment is usually at a temperature of less than 80° C. and therefore, the softening temperature of the adhesion layer is preferably 80° C. or more, and in view of proccessability, most preferably from 80 to 120° C. The softening point indicates a temperature at which the viscosity becomes 10¹² poises or less (10¹³ Pa·s or less), and the adhesive is usually fluidized within a time of approximately from 1 to 10 seconds at the above-described temperature.

As for the adhesive which flows under heating or pressure, the following thermoplastic resins are mainly representative. Examples of the adhesive which can be used include natural rubber (refractive index n=1.52), (di)enes such as polyisoprene (n=1.521), poly-1,2-butadiene (n=1.50), polyisobutene (n=1.505 to 1.51), polybutene (n=1.513), poly-2-heptyl-1,3-butadiene (n=1.50), poly-2-tert-butyl-1,3-butadiene (n=1.506) and poly-1,3-butadiene (n=1.515), polyethers such as polyoxyethylene (n=1.456), polyoxypropylene (n=1.450), polyvinyl ethyl ether (n=1.454), polyvinyl hexyl ether (n=1.459) and polyvinyl butyl ether (n=1.456), polyesters such as polyvinyl acetate (n=1.467) and polyvinyl propionate (n=1.467), polyurethane (n=1.5 to 1.6), ethyl cellulose (n=1.479), polyvinyl chloride (n=1.54 to 1.55), polyacrylonitrile (n=1.52), polymethacrylonitrile (n=1.52), polysulfone (n=1.633), polysulfide (n=1.6), phenoxy resin (n=1.5 to 1.6), and poly(meth)acrylic acid esters such as polyethyl acrylate (n=1.469), polybutyl acrylate (n=1.466), poly-2-ethylhexyl acrylate (n=1.463), poly-tert-butyl acrylate (n=1.464), poly-3-ethoxypropyl acrylate (n=1.465), polyoxycarbonyl tetramethylene (n=1.465), polymethyl acrylate (n=1.472 to 1.480), polyisopropyl methacrylate (n=1.473), polydodecyl methacrylate (n=1.474), polytetradecyl methacrylate (n=1.475), poly-n-propyl methacrylate (n=1.484), poly-3,3,5-trimethylcyclohexyl methacrylate (n=1. 484), polyethyl methacrylate (n=1.485), poly-2-nitro-2-methylpropyl methacrylate (n=1.487), poly-1,1-diethylpropyl methacrylate (n=1.489) and polymethyl methacrylate (n=1.489). Two or more of these acrylic polymers may be copolymerized or blended, if desired. Furthermore, a copolymerized resin of an acrylic resin with a polymer other than acryl, such as epoxy acrylate (n=1.48 to 1.60), urethane acrylate (n=1.5 to 1.6), polyether acrylate (n=1.48 to 1.49) and polyester acrylate (n=1.48 to 1.54), may also be used. Above all, urethane acrylate, epoxy acrylate and polyether acrylate are excellent in view of adhesive property. Examples of the epoxy acrylate include (meth)acrylic acid adducts of 1,6-hexanediol diglycidyl ether, neopentyl glycol diglycidyl ether, allyl alcohol diglycidyl ether, resorcinol diglycidyl ether, adipic acid diglycidyl ester, phthalic acid diglycidyl ester, polyethylene glycol diglycidyl ether, trimethylolpropane triglycidyl ether, glycerin triglycidyl ether, pentaerythritol tetraglycidyl ether, and sorbitol tetraglycidyl ether. A polymer having a hydroxyl group within its molecule, such as epoxy acrylate, is effective in enhancing the adhesive property. Two or more of these copolymerized resins may be used in combination, if desired. The softening point of the polymer becoming an adhesive is, in view of handleability, preferably 200° C. or less, more preferably 150° C. or less. Considering usage of the light diffusing film, the use environment is usually at 80° C. or less and therefore, the softening temperature of the adhesion layer is most preferably from 80 to 120° C. in view of proccessability. On the other hand, the mass average molecular weight (a mass average molecular weight measured using a calibration curve of standard polystyrene by gel permeation chromatography; hereinafter the same) of the polymer used is preferably 500 or more. When the molecular weight is 500 or more, the cohesive force of the adhesive composition is sufficiently brought out and the adhesion to an adherend can be unfailingly obtained. In the adhesive for use in the present invention, additives such as diluent, plasticizer, antioxidant, filler, colorant, ultraviolet absorbent and tackifier may be blended, if desired. The thickness of the adhesion layer is preferably from 5 to 80 μm, more preferably from 10 to 50 μm.

As for the material of the adhesive, bisphenol A-type epoxy resin, bisphenol F-type epoxy resin, tetrahydroxy-phenylmethane-type epoxy resin, novolak-type epoxy resin, resorcin-type epoxy resin, polyalcohol.polyglycol-type epoxy resin, polyolefin-type epoxy resin, and epoxy resin such as alicyclic or halogenated bisphenol, may be used (all have a refractive index of 1.55 to 1.60). Examples of the material other than epoxy resin include natural rubber (n=152), (di)enes such as polyisoprene (n=1.521), poly-1,2-butadiene (n=1.50), polyisobutene (n=1.505 to 1.51), polybutene (n=1.5125), poly-2-heptyl-1,3-butadiene (n=1.50), poly-2-tert-butyl-1,3-butadiene (n=1.506) and poly-1,3-butadiene (n=1.515), polyethers such as polyoxyethylene (n=1.4563), polyoxypropylene (n=1.4495), polyvinyl ethyl ether (n=1.454), polyvinyl hexyl ether (n=1.4591) and polyvinyl butyl ether (n=1.4563), polyesters such as polyvinyl acetate (n=1.4665) and polyvinyl propionate (n=1.4665), polyurethane (n=1.5 to 1.6), ethyl cellulose (n=1.479), polyvinyl chloride (n=1.54 to 1.55), polyacrylonitrile (n=1.52), polymethacrylonitrile (n=1.52), polysulfone (n=1.633), polysulfide (n=1.6), and phenoxy resin (n=1.5 to 1.6). These materials have a suitable visible light transmittance.

Other than these resins, there may be used poly(meth)acrylic acid esters such as polyethyl acrylate (n=1.4685), polybutyl acrylate (n=1.466), poly-2-ethylhexyl acrylate (n=1.463), poly-tert-butyl acrylate (n=1.4638), poly-3-ethoxypropyl acrylate (n=1.465), polyoxycarbonyl tetramethacrylate (n=1.465), polymethyl acrylate (n=l.472 to 1.480), polyisopropyl methacrylate (n=1.4728), polydodecyl methacrylate (n=1.474), polytetradecyl methacrylate (n=1.4746), poly-n-propyl methacrylate (n=1.484), poly-3,3,5-trimethylcyclohexyl methacrylate (n=1.484), polyethyl methacrylate (n=1.485), poly-2-nitro-2-methylpropyl methacrylate (n=1.4868), polytetracarbanyl methacrylate (n=1.4889), poly-1,1-diethylpropyl methacrylate (n=1.4889) and polymethyl methacrylate (n=1.4893). Two or more of these acrylic polymers may be copolymerized or blended, if desired.

Furthermore, a copolymerized resin of an acrylic resin with a polymer other than acryl, such as epoxy acrylate, urethane acrylate, polyether acrylate and polyester acrylate, may also be used. Above all, epoxy acrylate and polyether acrylate are excellent in view of adhesive property. Examples of the epoxy acrylate include (meth)acrylic acid adducts of 1,6-hexanediol diglycidyl ether, neopentyl glycol diglycidyl ether, allyl alcohol diglycidyl ether, resorcinol diglycidyl ether, adipic acid diglycidyl ester, phthalic acid diglycidyl ester, polyethylene glycol diglycidyl ether, trimethylolpropane triglycidyl ether, glycerin triglycidyl ether, pentaerythritol tetraglycidyl ether, and sorbitol tetraglycidyl ether. The epoxy acrylate has a hydroxyl group within its molecule and therefore, is effective in enhancing the adhesive property. Two or more of these copolymerized resins may be used in combination, if desired. The mass average molecular weight of the polymer used to become the main component of the adhesive is 1,000 or more. When the molecular weight is 1,000 or more, the cohesive force of the composition is sufficiently brought out and the adhesion to an adherend can be unfailingly obtained.

In addition to these materials, the adhesive may contain, for example, a monomer having a high refractive index and/or a metal oxide ultrafine particle having a high refractive index. Examples of the monomer having a high refractive index include bis(4-methacryloylthiophenyl)sulfide, vinylnaphthalene, vinylphenyl sulfide and 4-methacryloxyphenyl-4′-methoxyphenyl thioether. As for the metal oxide ultrafine particle having a high refractive index, it is preferred to contain a fine particle having a particle diameter of 100 nm or less, preferably 50 nm or less, and comprising an oxide of at least one metal selected from the group consisting of zirconium, titanium, alumina, indium, zinc, tin and antimony. The metal oxide ultrafine particle having a high refractive index is preferably an oxide ultrafine particle of at least one metal selected from the group consisting of Al, Zr, Zn, Ti, In and Sn, and specific examples thereof include ZrO₂, TiO₂, Al₂O₃, In₂O₃, ZnO, SnO₂, Sb₂O₃ and ITO. In particular, the adhesion layer preferably contains at least one inorganic fine particle selected from the group consisting of ZrO₂, TiO₂, SnO₂ and ZnO and in this case, the adhesion layer becomes a high refractive index layer. Among these, ZrO₂ is more preferred. The amount of the monomer or metal oxide ultrafine particle having a high refractive index added is preferably from 10 to 90 mass %, more preferably from 20 to 80 mass %, based on the total mass of the light-transmitting resin (31).

A curing agent (crosslinking agent) may also be used in the adhesive, and examples of the crosslinking agent which can be used include amines such as triethylenetetramine, xylenediamine and diaminodiphenylmethane, acid anhydrides such as phthalic anhydride, maleic anhydride, dodecylsuccinic anhydride, pyromellitic anhydride and benzophenonetetracarboxylic anhydride, diaminodiphenylsulfone, tris(dimethylaminomethyl)phenol, polyamide resin, dicyandiamide, and ethylmethylimidazole. One of these crosslinking agents may be used alone, or two or more thereof may be used as a mixture. The amount of the crosslinking agent added is preferably selected from the range of 0.1 to 50 parts by mass, preferably 1 to 30 parts by mass, per 100 parts by mass of the above-described polymer. If the amount added is less than 0.1 parts by mass, the curing becomes insufficient, whereas if it exceeds 50 parts by mass, excessive crosslinking results and adversely affects the adhesive property. In the resin composition of the adhesive for use in the present invention, additives such as diluent, plasticizer, antioxidant, filler, colorant and tackifier may be blended, if desired. The resin composition of the adhesive is coated to partially or entirely cover the substrate of a constituent material where a geometric pattern drawn with an electrically conductive material is provided on the surface of a transparent plastic substrate, and through drying of the solvent and curing under heating, the adhesive film according to the present invention is obtained. This adhesive film having electromagnetic wave shielding property and transparency is directly laminated to a display such as CRT, PDP, liquid crystal and EL by the adhesive of the adhesive film, or laminated to a plate or sheet such as acrylic plate or glass plate and then used for a display.

The adhesive is preferably transparent. Specifically, the total light transmittance is preferably 70% or more, more preferably 80% or more, and most preferably from 85 to 92%. Furthermore, the adhesive preferably has a low haze level. Specifically, the haze level is preferably from 0 to 3%, more preferably from 0 to 1.5%. The adhesive for use in the present invention is preferably colorless so as not to change the display color inherent in the display. However, even if the resin itself is colored, when the thickness of the adhesive is thin, the adhesive can be regarded as being substantially colorless. Also, in the case of intentionally coloring the adhesive. The transmittance and haze level are not in the ranges above.

Examples of the adhesive having the above-described properties include an acrylic resin, an α-olefin resin, a vinyl acetate-based resin, an acrylic copolymer-based resin, a urethane-based resin, an epoxy-based resin, a vinylidene chloride-based resin, a vinyl chloride-based resin, an ethylene-vinyl acetate-based resin, a polyamide-based resin and a polyester-based resin. Among these, an acrylic resin is preferred. Even when the same resin is used, the self-adhesive property can be enhanced by such a method as that, at the synthesis of the adhesive by a polymerization method, the amount of the crosslinking agent added is decreased, a tackifier is added, or the terminal group of the molecule is changed. Also, even with the use of the same adhesive, the adhesion can be enhanced by modifying the surface to which the adhesive is adhered, that is, by applying surface modification to the transparent plastic film or glass plate. Examples of the surface modification method include a physical method such as corona discharge treatment and plasma glow treatment, and a method of forming an underlayer for enhancing the adhesion.

In view of transparency, colorlessness and handleability, the thickness of the adhesive is preferably on the order of 1 to 50 μm. Specifically, the thickness is approximately from 1 to 20 μm. In the case where a change in the display color of the display itself is not caused and the transparency is in the range above, the thickness of the adhesive may exceed the above-described range.

### EXAMPLES

### <<Production of Light Diffusing Film>>

### (Preparation of Coating Solution (1) for Light Diffusing Layer)

100 Parts by mass of a zirconia ultrafine particle dispersion-containing hardcoat coating solution (DESOLITE KZ-7114A, produced by JSR) (average particle diameter of zirconia ultrafine particle: 0.05 μm) as a light-transmitting resin constituting the light diffusing layer and 57 parts by mass of a polymerizable monomer (polymerizable compound) (DPHA, produced by Nippon Kayaku Co., Ltd.) were mixed with stirring, and the mixture was dissolved in a solution of methyl ethyl ketone/methyl isobutyl ketone (20/80 by mass). This solution was mixed with 17 parts by mass of polymethyl methacrylate based bead (MX150, produced by Soken Chemical & Engineering Co., Ltd., particle diameter: 1.5 μm, refractive index: 1.49) as a light scattering particle and adjusted to a solid content of 50% with methyl ethyl ketone/methyl isobutyl ketone (20/80 by mass). Here, in order to measure the refractive index of the light-transmitting resin in a state of the particle being not mixed, a coating solution where the particle was not mixed was separately coated and ultraviolet-cured to form a coating film. The refractive index of the obtained coating film was 1.61.

### (Preparation of Coating Solutions (2) to (4) for Light Diffusing Layer)

100 Parts by mass of a zirconia ultrafine particle dispersion-containing hardcoat coating solution (DESOLITE KZ-7114A, produced by JSR) (average particle diameter of zirconia ultrafine particle: 0.05 μm) as a light-transmitting resin constituting the light diffusing layer and 57 parts by mass of a polymerizable monomer (polymerizable compound) (DPHA, produced by Nippon Kayaku Co., Ltd.) were mixed with stirring, and the mixture was dissolved in a solution of methyl ethyl ketone/methyl isobutyl ketone (20/80 by mass). The resulting solution was mixed with 17 parts by mass of amorphous silica-based bead as a light scattering particle and adjusted to a solid content of 50% with methyl ethyl ketone/methyl isobutyl ketone (20/80 by mass). At this time, three kinds of Coating Solutions (2) to (4) for Light Diffusing Layer were prepared using three kinds of amorphous silica-based beads, KE-P10, KE-P30 and KE-P50, produced by Nippon Shokubai Co., Ltd. The amorphous silica-based beads KE-P10, KE-P30 and KE-P50 had a particle diameter of 0.1 μm, 0.3 μm and 0.5 μm, respectively, and all had a refractive index of 1.43. Here, in order to measure the refractive index of the light-transmitting resin in a state of the particle being not mixed, a coating solution where the particle was not mixed was separately coated and ultraviolet-cured to form a coating film. The refractive index of the obtained coating film was 1.61.

### (Preparation of Coating Solution (5) for Light Diffusing Layer)

200 Parts by mass of a zirconia ultrafine particle dispersion-containing hardcoat coating solution (DESOLITE KZ-7114A, produced by JSR) as a light-transmitting resin constituting the light diffusing layer and 57 parts by mass of a polymerizable monomer (polymerizable compound) (DPHA, produced by Nippon Kayaku Co., Ltd.) were mixed with stirring, and the mixture was dissolved in a solution of methyl ethyl ketone/methyl isobutyl ketone (20/80 by mass). The resulting solution was adjusted to a solid content of 50%. Here, the average particle diameter of the zirconia ultrafine particle used as the light scattering particle was 0.05 μm and the refractive index was 2.18. In order to measure the refractive index of the light-transmitting resin, the coating solution prepared above was coated and ultraviolet-cured to form a coating film. The refractive index of the obtained coating film was 1.70.

### (Preparation of Coating Solution for Low Refractive Index Layer)

8 Parts by mass of MEK-ST (a methyl ethyl ketone (MEK) dispersion of SiO₂ sol having an average particle diameter of 10 to 20 nm and a solid content concentration of 30 parts by mass, produced by Nissan Chemical Industries, Ltd.) and 100 parts by mass of methyl ethyl ketone were added to 93 parts by mass of a thermally crosslinking fluorine-containing polymer (JN-7228, produced by JSR Corp.) having a refractive index of 1.42 and after stirring, the blend was filtered through a polypropylene-made filter having a pore size of 1 μm to prepare a coating solution for low refractive index layer.

### <Light Diffusing Film 1>

The coating solution (1) for light diffusing layer prepared above was coated on a triacetyl cellulose film (TD-80U, produced by FUJIFILM Corporation) such that the coated amount of the 1.5-μm polymethyl methacrylate-based bead became 0.4 g/m², and after drying the solvent, the coated layer was cured using an air-cooled metal halide lamp (manufactured by Eye Graphics Co., Ltd.) of 160 W/cm by irradiating an ultraviolet ray at an illuminance of 400 mW/cm ² and an irradiation dose of 300 mJ/cm² to produce Light Diffusing Film 1. In this film, the dry thickness of the light diffusing layer was 3.0 μm. The haze value of the film was 65%.

### <Light Diffusing Film 2>

The coating solution for low refractive index layer prepared above was coated by a bar coater on a triacetyl cellulose film (TD-80U, produced by FUJIFILM Corporation), then dried at 80° C. and further thermally crosslinked at 120° C. for 10 minutes to form a low refractive index layer of 3.0 μm in thickness. Subsequently, the coating solution (1) for light diffusing layer prepared above was coated on the low refractive index layer such that the coated amount of the 1.5-μm polymethyl methacrylate-based bead became 0.4 g/m², and after drying the solvent, the coated layer was cured using an air-cooled metal halide lamp (manufactured by Eye Graphics Co., Ltd.) of 160 W/cm by irradiating an ultraviolet ray at an illuminance of 400 mW/cm² and an irradiation dose of 300 mJ/cm² to produce Light Diffusing Film 2. In this film, the dry thickness of the light diffusing layer was 3.0 μm. The haze value of the film was 65%.

<Light Diffusing Films a to c>

Coating Solutions (2) to (4) for Light Diffusing Layer prepared above each was coated on a triacetyl cellulose film (TD-80U, produced by Fujifilm Corp.) such that the coated amount of the amorphous silica-based bead became 0.4 g/m². After drying the solvent, the coated layer was cured using an air-cooled metal halide lamp (manufactured by Eye Graphics Co., Ltd.) of 160 W/cm by irradiating an ultraviolet ray at an illuminance of 400 mW/cm² and an irradiation dose of 300 mJ/cm² to produce Light Diffusing Films a to c. In these films, the dry thickness of the light diffusing layer was 3.0 μm. The haze value of the film was a: 15%, b: 65% and c: 65%.

<Light Diffusing Films d to f>

The coating solution for low refractive index layer prepared above was coated by a bar coater on a triacetyl cellulose film (TD-80U, produced by Fujifilm Corp.), then dried at 80° C. and further thermally crosslinked at 120° C. for 10 minutes to form a low refractive index layer of 3.0 μm in thickness. Subsequently, Coating Solutions (2) to (4) for Light Diffusing Layer prepared above each was coated on the low refractive index layer such that the coated amount of the amorphous silica-based bead became 0.4 g/m², and after drying the solvent, the coated layer was cured using an air-cooled metal halide lamp (manufactured by Eye Graphics Co., Ltd.) of 160 W/cm by irradiating an ultraviolet ray at an illuminance of 400 mW/cm² and an irradiation dose of 300 mJ/cm² to produce Light Diffusing Films d to f. In these films, the dry thickness of the light diffusing layer was 3.0 μm. The haze value of the film was d: 15%, e: 65% and f: 65%.

<Light Diffusing Film g>

Coating Solution (5) for Light Diffusing Layer prepared above was coated on a triacetyl cellulose film (TD-80U, produced by Fujifilm Corp.) to a thickness of 6 μm and after drying the solvent, the coated layer was cured using an air cooled metal halide lamp (manufactured by Eye Graphics Co., Ltd.) of 160 W/cm by irradiating an ultraviolet ray at an illuminance of 400 mW/cm² and an irradiation dose of 300 mJ/cm² to produce Light Diffusing Film g containing a zirconia fine particle. In this film, the dry thickness of the light diffusing layer was 3.0 μm. The haze value of the film was 10%.

<Light Diffusing Film h>

The coating solution for low refractive index layer prepared above was coated by a bar coater on a triacetyl cellulose film (TD-80U, produced by Fujifilm Corp.), then dried at 80° C. and further thermally crosslinked at 120° C. for 10 minutes to form a low refractive index layer of 3.0 μm in thickness. Subsequently, Coating Solution (5) for Light Diffusing Layer prepared above was coated on the low refractive index layer to a thickness of 6 μm and after drying the solvent, the coated layer was cured using an air-cooled metal halide lamp (manufactured by Eye Graphics Co., Ltd.) of 160 W/cm by irradiating an ultraviolet ray at an illuminance of 400 mW/cm² and an irradiation dose of 300 mJ/cm² to produce Light Diffusing Film h containing a zirconia fine particle. In this film, the dry thickness of the light diffusing layer was 3.0 μm. The haze value of the film was 10%.

### <Color Filter>

The following curable compositions in three colors each was dispersed over one day and one night.

(Green)

| | |
|---|---|
| Benzyl methacrylate/methacrylic | 80 parts by mass |
| acid copolymer | |
| (weight average molecular | |
| weight: 30,000, acid value: | |
| 120) | |
| Propylene glycol monomethyl | 500 parts by mass |
| ether acetate | |
| Copper phthalocyanine pigment | 33 parts by mass |
| C.I. Pigment Yellow 185 | 67 parts by mass |

(Red)

| | |
|---|---|
| Benzyl methacrylate/methacrylic | 80 parts by mass |
| acid copolymer | |
| (weight average molecular | |
| weight: 30,000, acid value: | |
| 120) | |
| Propylene glycol monomethyl | 500 parts by mass |
| ether acetate | |
| Pigment Red 254 | 50 parts by mass |
| Pigment Red PR177 | 50 parts by mass |

(Blue)

| | |
|---|---|
| Benzyl methacrylate/methacrylic | 80 parts by mass |
| acid copolymer | |
| (weight average molecular | |
| weight: 30,000, acid value: | |
| 120) | |
| Propylene glycol monomethyl | 500 parts by mass |
| ether acetate | |
| Pigment Blue 15:6 | 95 parts by mass |
| Pigment Violet 23 | 5 parts by mass |

Subsequently, the following components were added.

| | |
|---|---|
| Dipentaerythritol | 80 parts by mass |
| hexaacrylate (DPHA) | |
| TiO₂ (titania fine particle, | 100 parts by mass |
| average particle diameter | |
| (average diameter): 150 nm, | |
| refractive index: 2.54) | |
| 4-[o-Bromo-p-N,N-di(ethoxy- | 5 parts by mass |
| carbonyl)aminophenyl]-2,6- | |
| di(trichloromethyl)-S- | |
| triazine | |
| 7-[{4-chloro-6-(diethyl- | 2 parts by mass |
| amino)-S-triazin-2-yl}amino]- | |
| 3-phenylcoumarin | |
| Hydroquinone monomethyl ether | 0.01 parts by mass |
| Propylene glycol monomethyl | 500 parts by mass |
| ether acetate | |

The above-described components were uniformly mixed, and the resulting mixture was filtered through a filter having a pore size of 5 μm. In this way, curable compositions in three colors according to the present invention were obtained. Out of these compositions, the green curable composition was coated by a spin coater on a glass substrate for the production of a color filter to have a dry thickness of 2.0 μm and then dried at 120° C. for 2 minutes, whereby a green uniform coating film was formed.

The coating film was then irradiated with light at a wavelength of 365 nm through a mask of 100 μm by using an exposure apparatus at an exposure dose of 300 mJ/cm², and after the irradiation, the coating film was developed with 10% CD (produced by Fujifilm Arch Co., Ltd.) at 26° C. for 60 seconds, then rinsed with running water for 20 seconds, dried by an air knife and further heat-treated at 220° C. for 60 minutes to form a green pattern image (green pixels). Using the red and blue curable compositions, the operation above was performed in the same manner on the same glass substrate to sequentially form a red pattern image (red pixels) and a blue pattern image (blue pixels), whereby the color filter according to the present invention was obtained. The green pixel, red pixel and blue pixel (cured product of curable composition) had a refractive index of 1.80, 1.78 and 1.82 at wavelengths of 550 nm, 630 nm and 450 nm, respectively at which a light can transmit.

### <Adhesive>

10 Parts by mass of zirconium oxide ultrafine particle was incorporated into 90 parts by mass of a transparent adhesive comprising an acrylic acid ester polymer to obtain a transparent adhesive having a refractive index of 1.61.

### <<Production of Multicolor Organic EL Display Device>>

The top-emission type organic EL display device of the present invention is described below.

First, TFT is formed on an insulating substrate through a buffer layer. Next, an interlayer insulating film layer comprising an SiN film is deposited on the entire surface, and contact holes reaching the source region and drain region, respectively, are formed using a normal photoetching process.

Subsequently, an electrically conductive layer having an Al/Ti/Al multilayer structure is deposited on the entire surface and then patterned using a normal photoetching process, whereby a source electrode is formed to extend also over the TFT part and at the same time, a drain electrode is formed.

Incidentally, the source electrode is branched into four branch lines from a common source line.

Thereafter, a photosensitive resin is coated on the entire surface by using, for example, a spin coating method to form an interlayer insulating film, and the interlayer insulating film is exposed through a predetermined mask and then developed with a predetermined developer, whereby contact holes corresponding to the branch lines of the source electrode are formed.

Furthermore, an Al film is deposited on the entire surface, for example, by a sputtering method and then patterned into a predetermined configuration by using a normal photoetching process, whereby a divided lower electrode connecting to the branch line of the source electrode through a contact hole is formed.

Subsequently, an organic EL layer covering the divided lower electrode exposed to the bottom of a pixel opening is formed by a mask vapor-deposition method, and an Al film having a thickness of, for example, 10 nm and an ITO film having a thickness of, for example, 30 nm, covering the organic EL layer, are sequentially deposited again using the mask vapor-deposition method to form a common upper electrode, where the regions corresponding to respective divided lower electrodes each becomes a divided pixel part.

Thereafter, an SiN film and an SiON film were sequentially deposited on the entire surface by a CVD method to form a barrier layer of 5 μm in thickness, and a glass plate as a transparent substrate is further laminated to the barrier layer.

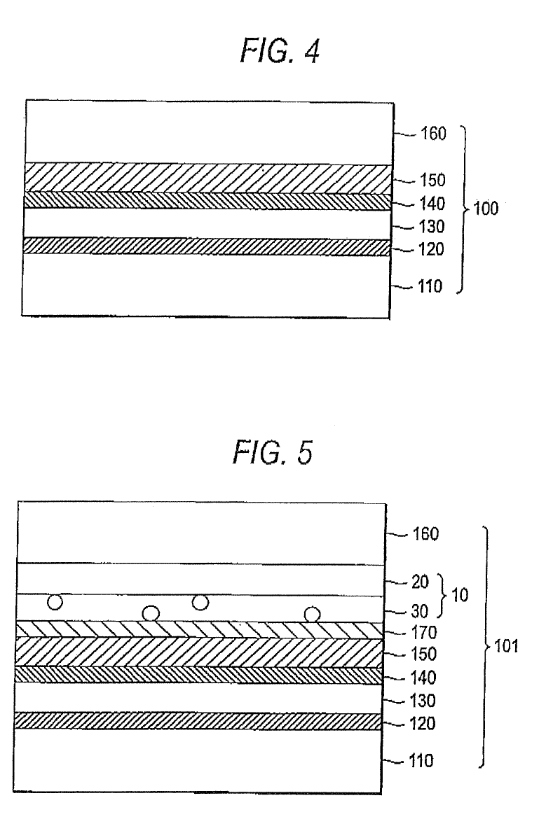

FIG. 4 shows a simplified basic construction of an organic EL device 100. A lower electrode 120 is formed on a TFT substrate 110, and an organic EL layer 130, an upper electrode 140, a barrier layer 150 and a transparent substrate 160 are sequentially formed thereon.

### Example 1

The embodiment 101 of Example 1 is shown in FIG. 5. The adhesive prepared above is coated on the barrier layer 150 to a thickness of 10 μm to provide an adhesion layer 170, and Light Diffusing Film 1 (10 in the Figure) is laminated thereon by arranging the light diffusing layer to come into contact with the adhesion layer 170. Furthermore, a transparent substrate 160 is laminated thereon.

### Example 2

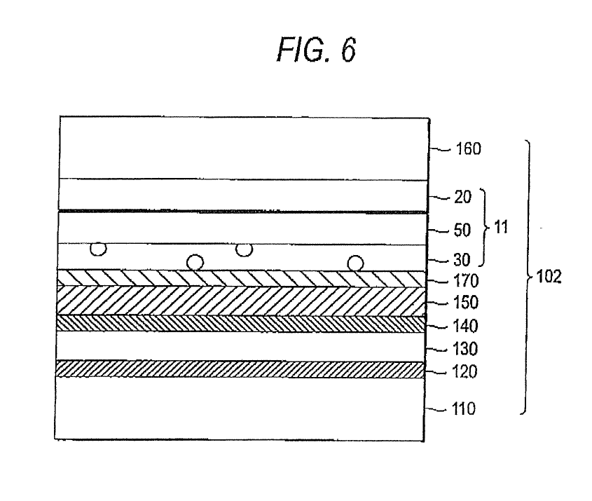

The embodiment 102 of Example 2 is shown in FIG. 6. The adhesive prepared above is coated on the barrier layer 150 to a thickness of 10 μm to provide an adhesion layer 170, and Light Diffusing Film 2 (11 in the Figure) is laminated thereon by arranging the light diffusing layer to come into contact with the adhesion layer 170. Furthermore, a transparent substrate 160 is laminated thereon.

### Example 3

In Example 3, the color material surface of the color filter formed above on a glass substrate is laminated to the barrier layer of the organic EL display device through the ZrO₂-containing adhesion layer (thickness: 10 μm).

### Examples 4 to 6

The embodiment 101 of Examples 4 to 6 is shown in FIG. 5. The adhesive prepared above is coated on the barrier layer 150 to a thickness of 10 μm to provide an adhesion layer 170, and a light diffusing film (10 in the Figure) is laminated thereon by arranging the light diffusing layer to come into contact with the adhesion layer 170. Furthermore, a transparent substrate 160 is laminated thereon. Examples 4 to 6 correspond to Light Diffusing Films a to c, respectively.

### Examples 7 to 9

The embodiment 102 of Examples 7 to 9 is shown in FIG. 6. The adhesive prepared above is coated on the barrier layer 150 to a thickness of 10 μm to provide an adhesion layer 170, and a light diffusing film (11 in the Figure) is laminated thereon by arranging the light diffusing layer to come into contact with the adhesion layer 170. Furthermore, a transparent substrate 160 is laminated thereon. Examples 7 to 9 correspond to Light Diffusing Films d to f, respectively.

### Example 10

The embodiment 101 of Example 10 is shown in FIG. 5. The adhesive prepared above is coated on the barrier layer 150 to a thickness of 10 μm to provide an adhesion layer 170, and a light diffusing film (10 in the Figure) is laminated thereon by arranging the light diffusing layer to come into contact with the adhesion layer 170. Furthermore, a transparent substrate 160 is laminated thereon. Example 10 corresponds to Light Diffusing Film g.

### Example 11

The embodiment 102 of Example 11 is shown in FIG. 6. The adhesive prepared above is coated on the barrier layer 150 to a thickness of 10 μm to provide an adhesion layer 170, and a light diffusing film (11 in the Figure) is laminated thereon by arranging the light diffusing layer to come into contact with the adhesion layer 170. Furthermore, a transparent substrate 160 is laminated thereon. Example 11 corresponds to Light Diffusing Film h.

### Comparative Example 1

The basic construction of an organic EL device shown in FIG. 4 is used in Comparative Example 1. The adhesive prepared above is coated on the barrier layer 150 to a thickness 10 μm, and a transparent substrate 160 is laminated thereon.

### Comparative Example 2

The adhesive prepared above is coated on the barrier layer 150 in FIG. 4 to a thickness of 10 μm, and a transparent substrate 160 having a thickness of 0.7 mm is laminated thereon. Furthermore, the adhesive prepared above is coated thereon to a thickness of 10 μm, and Light Diffusing Film 1 is laminated thereon by arranging the light diffusing layer to come into contact with the adhesive.

### Comparative Example 3

100 Parts by mass of a mixture of dipentaerythritol hexaacrylate and dipentaerythritol pentaacrylate {“DPHA”, produced by Nippon Kayaku Co., Ltd.) was diluted with 100 parts by mass of methyl isobutyl ketone. Furthermore, 5 parts by mass of a polymerization initiator {“IRGACURE 184”, produced by Ciba Specialty Chemicals K.K.} was added, and the blend was mixed with stirring. Subsequently, 0.1 parts by mass of a fluorine-containing surface modifier (FP-149) and 20 parts by mass of a silane coupling agent {“KBM-5103”, produced by Shin-Etsu Chemical Co., Ltd.} were added. The refractive index of a coating film obtained by coating the resulting solution and then ultraviolet-curing the coating was 1.520. A spin coating solution was prepared by formulating the solution composition of the coating solution for light diffusing layer to contain 25 parts by mass of TiO₂ having an average particle diameter of 300 nm as a light scattering particle. This spin coating solution was spin-coated on the barrier layer 150 in FIG. 4 to a thickness of 1.5 μm and after drying the solvent, the coated layer was cured using an air-cooled metal halide lamp (manufactured by Eye Graphics Co., Ltd.) of 160 W/cm by irradiating an ultraviolet ray at an illuminance of 400 mW/cm2 and an irradiation dose of 300 mJ/cm² to form a light diffusing layer. Furthermore, the adhesive prepared above was coated on the light diffusing layer to a thickness of 10 μm, and a transparent substrate 160 was laminated thereon.

In the foregoing pages, working examples of the present invention are described, but the present invention is not limited to the conditions and constructions in these Examples and various changes or modifications can be made. For example, the materials and layer structure constituting the organic EL layer of each Example are given by way of illustration only, and the material of the organic layer can be appropriately selected from known organic EL materials according to the emission color.

An image was displayed on the organic EL display device and the brightness was evaluated in a sensory manner by the following three criteria.

A: Bright.

B: Slightly dark.

C: Dark.

Also, an image was displayed on the organic EL display device, and the image blur was evaluated in a sensory manner by the following three criteria.

A: Image blur was not recognized at all.

B: Image was slightly blurred.

C: Image blur was recognized.

Whether the finished display was good or bad was evaluated by the following two criteria from the standpoint that the brightness was enhanced and the image blur was not recognized.

A; A or B in brightness and A or B in image blur.

B: C in either brightness or image blur.

The results of Examples 1 to 3 and Comparative Examples 1 to 3 are shown in Table 1. Also, the results of Examples 4 to 11 are shown in Table 2.

TABLE 1

| | Brightness | Image Blur | Judgment |
|---|---|---|---|
| Comparative Example 1 | C | A | B |
| Comparative Example 2 | A | C | B |
| Comparative Example 3 | C | A | B |
| Example 1 | B | A | A |
| Example 2 | A | A | A |
| Example 3 | A | A | A |

TABLE 2

| | Light | Particle | | | |
|---|---|---|---|---|---|
| | Scattering | Diameter | | Image | |
| | Particle | (μm) | Brightness | Blur | Judgment |
| Example 4 | amorphous | 0.1 | B | A | A |
| | silica-based | | | | |
| | bead | | | | |
| Example 5 | amorphous | 0.3 | B | A | A |
| | silica-based | | | | |
| | bead | | | | |
| Example 6 | amorphous | 0.5 | B | A | A |
| | silica-based | | | | |
| | bead | | | | |
| Example 7 | amorphous | 0.1 | A | A | A |
| | silica-based | | | | |
| | bead | | | | |
| Example 8 | amorphous | 0.3 | A | A | A |
| | silica-based | | | | |
| | bead | | | | |
| Example 9 | amorphous | 0.5 | A | A | A |
| | silica-based | | | | |
| | bead | | | | |
| Example 10 | zirconia | 0.05 | B | A | A |
| | (ZrO₂) | | | | |
| Example 11 | zirconia | 0.05 | A | A | A |
| | (ZrO₂) | | | | |

In Examples 10 to 11, even when a light scattering particle having a refractive index of 1.8 or more other than ZrO₂ was used, the same effects were obtained.

As described in Background Art, the cause of the low light extraction efficiency of a self-emission display device resides in that when light generated inside of the display device becomes incident at a large angle on the interface with an adjacent layer differing in the refractive index, the light is totally reflected and all waveguided through the inside of the display derive and cannot be extracted to the outside.

On the other hand, when a scattering member having a light scattering layer composed of a transparent resin composition and a light scattering particle differing in the refractive index from the resin composition is introduced into an organic EL display device, it becomes possible to extract the light to the outside. That is, the traveling direction of light caused to be waveguided through layers due to total reflection is bent by the action of light scattering, whereby light extraction to the outside can be realized.

At this time, by setting the refractive index of the transparent resin composition to be equal to or greater than the refractive index of the organic light-emitting layer, light being waveguided inside of the high refractive index layer including the organic light-emitting layer can be extracted.

Also, when the scattering member is introduced such that the light scattering layer is formed right above the upper electrode, the distance between the light emitting point and the scattering layer can be narrowed and the resolution of an image can be prevented from deteriorating due to light scattering. Furthermore, in order to more elevate the light extraction efficiency, it is preferred to increase the number of occurrences of light scattering. To this end, the number of occurrences of total reflection in the high refractive index layer including the organic light-emitting layer is preferably increased, which can be realized by thinning the high refractive index layer including the organic light-emitting layer.

In addition, the light extraction efficiency can be further more enhanced by setting the layer in contact with the high refractive index layer including the organic light-emitting layer to have a low refractive index.

Also, when a scattering member having a light scattering layer is previously formed, the processing of incorporating a light scattering layer into an organic EL display device can be facilitated. Furthermore, the previous formation of a scattering member having a light scattering layer enables it easy to impart an arbitrary scattering property to the scattering layer.

By virtue of these effects, a scattering member optimal to the organic EL of the present invention can be obtained. Accordingly, the scattering member, light diffusing film or color filter for use in the present invention and the method for laminating such a member are useful in view of both processing suitability and optical property.

The entire disclosure of each and every foreign patent application from which the benefit of foreign priority has been claimed in the present application is incorporated herein by reference, as if fully set forth.

What is claimed is:

1. An organic electroluminescent display device, comprising:
a substrate;
a lower electrode;
an organic electroluminescent layer; and
an upper electrodes in this order,
wherein the organic electroluminescent display device further comprises a scattering member on or above the upper electrode.

2. The organic electroluminescent display device according to claim 1,
wherein the scattering member is a light diffusing film.

3. The organic electroluminescent display device according to claim 2,
wherein the light diffusing film contains:
a transparent substrate film; and
a light diffusing layer that contains:
a transparent resin composition; and
a light scattering particle, the light scattering particle having a refractive index different from a refractive index of the transparent resin composition,
wherein the refractive index of the transparent resin composition contained in the light diffusing layer is 1.6 or more.

4. The organic electroluminescent display device according to claim 3,
wherein the transparent resin composition of the light diffusing layer contains at least one kind of an inorganic fine particle selected from the group consisting of ZrO₂, TiO₂, SnO₂ and ZnO.

5. The organic electroluminescent display device according to claim 3,
wherein the refractive index of the light scattering particle contained in the light diffusing layer is 1.55 or less.

6. The organic electroluminescent display device according to claim 3,
wherein an average diameter of the light scattering particle contained in the light diffusing layer is from 0.1 to 2.0 μ.

7. The organic electroluminescent display device according to claim 2,
wherein the light diffusing film contains:
a transparent substrate film; and
a light diffusing layer that contains:
a transparent resin composition; and
at least one kind of fine particle selected from the group consisting of ZrO₂, TiO₂, SnO₂ and ZnO contained in the transparent resin composition, the at least one kind of fine particle having an average particle diameter of 50 to 300 nm.

8. The organic electroluminescent display device according to claim 3,
wherein the light diffusing film further contains a low refractive index layer between the transparent substrate film and the light diffusing layer.

9. The organic electroluminescent display device according to claim 8,
wherein a refractive index of the low refractive index layer is 1.45 or less.

10. The organic electroluminescent display device according to claim 8,
wherein the low refractive index layer contains a hollow silica.

11. The organic electroluminescent display device according to claim 1,
wherein the scattering member is a color filter.

12. The organic electroluminescent display device according to claim 11,
wherein the color filter is obtained by curing a curable composition containing a colorant and a light scattering particle.

13. The organic electroluminescent display device according to claim 12,
wherein a refractive index of the curable composition at the curing is 1.6 or more.

14. The organic electroluminescent display device according to claim 12,
wherein the curable composition contains at least one kind of an inorganic fine particle selected from the group consisting of ZrO₂, TiO₂, SnO₂ and ZnO.

15. The organic electroluminescent display device according to claim 12,
wherein a refractive index of the light scattering particle is 1.55 or less.

16. The organic electroluminescent display device according to claim 12,
wherein an average diameter of the light scattering particle is from 0.1 to 2.0 μm.

17. The organic electroluminescent display device according to claim 12,
wherein the light scattering particle is at least one kind of fine particle selected from the group consisting of ZrO₂, TiO₂, SnO₂ and ZnO having an average particle diameter of 50 to 300 nm.

18. The organic electroluminescent display device according to claim 1,
wherein the scattering member is laminated directly on the upper electrode.

19. The organic electroluminescent display device according to claim 1,
wherein the scattering member is laminated on the upper electrode through a barrier layer and laminated directly on the barrier layer.

20. The organic electroluminescent display device according to claim 2,
wherein the light diffusing film is laminated on the upper electrode or a barrier layer provided on the upper electrode through an adhesion layer.

21. The organic electroluminescent display device according to claim 20,
wherein a refractive index of the adhesion layer is 1.6 or more.

22. The organic electroluminescent display device according to claim 20,
wherein the adhesion layer contains at least one kind of an inorganic fine particle selected from the group consisting of ZrO₂, TiO₂, SnO₂ and ZnO.
